(19) United States
(12) Patent Application Publication
(10) Pub. No.: US 2012/0267664 A1
(43) Pub. Date: Oct. 25, 2012

(54) NITRIDE-BASED SEMICONDUCTOR LIGHT-EMITTING DEVICE AND METHOD FOR FABRICATING THE SAME

(75) Inventors: Songbaek CHOE, Osaka (JP); Naomi ANZUE, Osaka (JP); Ryou KATO, Osaka (JP); Toshiya YOKOGAWA, Nara (JP)

(73) Assignee: PANASONIC CORPORATION, Osaka (JP)

(21) Appl. No.: 13/444,131

(22) Filed: Apr. 11, 2012

(30) Foreign Application Priority Data
Apr. 22, 2011 (JP) 2011-096467

(51) Int. Cl. H01L 33/50; H01L 33/40; H01L 33/32

(52) U.S. Cl. 257/98; 438/46; 257/99; 257/E33.028; 257/E33.063; 257/E33.067

(57) ABSTRACT

A method for fabricating a nitride-based semiconductor light-emitting device includes a step (a) of forming a nitride-based semiconductor multi-layer structure (20) including a p-type Al_{d}GaₑN layer (25) having an m-plane as a growing plane, and a step (b) of forming an Ag electrode (30) so as to be in contact with a growing plane (13) of the p-type Al_{d}GaₑN layer (25). The step (b) includes a step (b1) of forming the Ag electrode (30) having a thickness in the range of 200 nm or more to 1,000 nm or less, and a step (b2) of heating the Ag electrode (30) to a temperature in the range of 400° C. or more to 600° C. or less.

### BACKGROUND

1. Technical Field

The disclosure relates to a nitride-based semiconductor light-emitting device and a method for fabricating such a device. The present disclosure also relates to a method of making an electrode for use in such a nitride-based semiconductor light-emitting device.

2. Description of the Related Art

A nitride semiconductor including nitrogen (N) as a Group V element is a prime candidate for a material to make a short-wave light-emitting device because its bandgap is sufficiently wide. Among other things, nitride-based compound semiconductors (AlₓGa_{y}In_{z}N (where 0≦x, y, z≦1 and x+y+z=1)) have been researched and developed particularly extensively. As a result, blue light-emitting diodes (LEDs), green LEDs, and semiconductor laser diodes made of GaN-based semiconductors have already been used in actual products (for example, Japanese Patent Application Laid-open No. 2001-308462, Japanese Patent Application Laid-open No. 2003-332697).

A nitride-based semiconductor has a wurtzite crystal structure. FIG. 1 schematically illustrates a unit cell of GaN. In an AlₓGa_{y}In_{z}N (where 0≦x, y, z≦1 and x+y+z=1) semiconductor crystal, some of the Ga atoms shown in FIG. 1 may be replaced with Al and/or In atoms.

FIG. 2 shows four fundamental vectors a₁, a₂, a₃ and c, which are generally used to represent planes of a wurtzite crystal structure with four indices (i.e., hexagonal indices). The fundamental vector c runs in the [0001] direction, which is called a “c-axis”. A plane that intersects with the c-axis at right angles is called either a “c-plane” or a “(0001) plane”. It should be noted that the “c-axis” and the “c-plane” are sometimes referred to as “C-axis” and “C-plane”.

In fabricating a semiconductor device using nitride-based semiconductors, a c-plane substrate, i.e., a substrate of which the principal surface is a (0001) plane, is used as a substrate on which nitride-based semiconductor crystals are grown. In a c-plane, however, there is a slight shift in the c-axis direction between a Ga atom layer and a nitrogen atom layer, thus producing electrical polarization there. That is why the c-plane is also called a “polar plane”. As a result of the electrical polarization, a piezoelectric field is generated in the InGaN quantum well of the active layer in the c-axis direction. Once such a piezoelectric field has been generated in the active layer, due to the quantum confinement Stark effect of carriers, some positional deviation occurs in the distributions of electrons and holes in the active layer. Consequently, the internal quantum yield decreases, thus increasing the threshold current in a semiconductor laser diode and increasing the power dissipation and decreasing the luminous efficacy in an LED. Meanwhile, as the density of injected carriers increases, the piezoelectric field is screened, thus varying the emission wavelength, too.

Thus, to overcome these problems, it has been proposed that a substrate of which the principal surface is a non-polar plane such as a (10-10) plane that is perpendicular to the [10-10] direction and that is called an “m-plane” be used. As used herein, “−” attached on the left-hand side of a Miller-Bravais index in the parentheses means a “bar”. As shown in FIG. 2, the m-plane is parallel to the c-axis (i.e., the fundamental vector c) and intersects with the c-plane at right angles. On the m-plane, Ga atoms and nitrogen atoms are on the same atomic-plane. For that reason, no electrical polarization is produced perpendicularly to the m-plane. That is why if a semiconductor multilayer structure is formed perpendicularly to the m-plane, no piezoelectric field is generated in the active layer, thus overcoming the problems described above. The “m-plane” is a generic term that collectively refers to a family of planes including (10-10), (−1010), (1-100), (−1100), (01-10) and (0-110) planes. Also, as used herein, the “X-plane growth” means epitaxial growth that is produced perpendicularly to the X plane (where X=c or m) of a hexagonal wurtzite structure. As for the X-plane growth, the X plane is sometimes referred to herein as a “growing plane”. A layer of semiconductor crystals that have been formed as a result of the X-plane growth is sometimes referred to herein as an “X-plane semiconductor layer”.

An LED fabricated using the substrate having the non-polar plane as described above can realize the improvement of luminous efficacy as compared with a conventional device provided on the c-plane.

In a general flip-chip type LED, a part of light released from the active layer is reflected by a p-electrode so as to be emitted to the outside of a semiconductor layer through a substrate. In this case, in order to externally extract the light emitted from the active layer of the LED with high efficiency, it is important to form the p-electrode having a high reflectance. As a material having a high reflectance, which is used for the p-electrode, Ag is known.

It is also important to lower a contact resistance of the p-electrode. In general, it is known that the contact resistance of the p-electrode can be reduced by performing heat treatment.

When Ag is used for the p-electrode, however, aggregation is likely to occur due to the heat treatment. The aggregation is a phenomenon in which a surface area is reduced to be as small as possible so as to reduce excessive free energy (surface energy) present on a surface of a metal film. When the heat treatment is conducted, Ag atoms migrate in the film due to the aggregation. As a result, a film-surface roughness is increased or holes are generated in the film in some cases. Accordingly, there is a problem in that the reflectance is lowered by the aggregation of Ag, resulting in the prevention of the light emitted from the active layer of the LED from being externally extracted with high efficiency.

For example, Japanese Patent Application Laid-open No. 2005-197687 relating to the nitride-based semiconductor light-emitting device having the c-plane as a principal surface discloses the use of Zn, Rh, Mg, Au, Ni, or Cu, an alloy thereof, or a doped In-oxide for an aggregation-prevention layer to be provided on a reflective electrode. Japanese Patent Application Laid-open No. 2005-197687 reports that the aggregation in the reflective electrode can be prevented to realize low contact resistance by providing a Ni-based alloy as a contact electrode at an interface between the reflective electrode made of Ag, Rh, Al, or Sn and the semiconductor layer.

Moreover, Japanese Patent Application Laid-open No. 2010-56423 relating to a semiconductor light-emitting device similarly having the c-plane as the principal surface discloses that the aggregation of Ag can be prevented to lower the contact resistance by providing an Ag alloy layer containing Ag as a main component and Pd or Cu intentionally mixed therein, so as to be included in the p-electrode.

WO 2010/113405 discloses the formation of a p-electrode including a Zn layer and an Ag layer on a nitride-based semiconductor multilayer structure including a p-type semiconductor region having the m-plane as a surface.

WO 2010/113406 discloses the formation of an Mg layer and a p-electrode including the Mg layer on a nitride-based semiconductor multilayer structure including a p-type semiconductor region having the m-plane as a surface.

### SUMMARY

As described above, a GaN-based semiconductor device that has been grown on an m-plane substrate would achieve far more beneficial effects than what has been grown on a c-plane substrate, because the GaN-based semiconductor device grown on the m-plane substrate has no electrical polarization in growing direction, but still has the following drawback. Specifically, when the Ag electrode is formed on the GaN-based semiconductor device provided on the m-plane substrate, there arises a problem in that the aggregation of Ag is more likely to occur than in the Ag electrode formed on the GaN-based semiconductor device provided on the c-plane substrate.

One non-limiting, and exemplary embodiment provides an electrode structure and a method for fabricating the same, which are capable of suppressing a reduction in reflectance due to aggregation in an Ag electrode provided on a GaN-based semiconductor light-emitting device which is crystally grown on an m-plane substrate.

According to an exemplary embodiment of the present disclosure, there is provided a method for fabricating a nitride-based light-emitting device, including: a step (a) of forming a nitride-based semiconductor multilayer structure including a p-type semiconductor region having an m-plane as a growing plane; and a step (b) of forming an Ag electrode so as to be in contact with the growing plane of the p-type semiconductor region, in which the step (b) includes: a step (b1) of forming the Ag electrode having a thickness in a range of 200 nm or more to 1,000 nm or less; and a step (b2) of heating the Ag electrode to a temperature in a range of 400° C. or more to 600° C. or less.

According to the general aspect, a reduction in reflectance due to the aggregation of Ag can be suppressed to realize the light-emitting device having high light-emitting efficiency and power efficiency.

These general and specific aspects may be implemented using a system, a method, and a computer program, and any combination of systems, methods, and computer programs.

Additional benefits and advantages of the disclosed embodiments will be apparent from the specification and Figures. The benefits and/or advantages may be individually provided by the various embodiments and features of the specification and drawings disclosure, and need not all be provided in order to obtain one or more of the same.

### BRIEF DESCRIPTION OF THE DRAWINGS

FIG. 1 is a perspective view schematically illustrating a unit lattice of GaN.

FIG. 2 is a perspective view illustrating primitive translation vectors a₁, a₂, and a₃ of a wurtzite crystal structure.

FIGS. 3A to 3C are views illustrating fabrication steps of a nitride-based semiconductor light-emitting device 100 according to an embodiment of the present disclosure.

FIG. 4A is a schematic sectional view of the nitride-based semiconductor light-emitting device 100 according to the embodiment of the present disclosure, FIG. 4B is a view illustrating a crystal structure on an m-plane, and FIG. 4C is a view illustrating a crystal structure on a c-plane.

FIGS. 5A to 5D are graphs showing the relation between specific contact resistance of an Ag electrode formed on an m-plane nitride-based semiconductor layer and a measured current value when a temperature of heat treatment is varied from 400° C. to 700° C.

FIG. 6 is a graph showing the dependence of a current-voltage characteristic of the Ag electrode formed on the m-plane nitride-based semiconductor layer on a heat-treatment temperature.

FIGS. 7A to 7C are graphs showing the relation between the specific contact resistance and the measured current value when the heat treatment is conducted under conditions of different temperatures and times for the Ag electrode formed on the m-plane nitride-based semiconductor layer.

FIGS. 8A and 8B are graphs showing the relation between the specific contact resistance of the Ag electrode formed on a c-plane nitride-based semiconductor layer and a measured current value, and the current-voltage characteristic, respectively.

FIG. 9 is a graph showing the dependence of the specific contact resistances of the Ag electrodes formed on the m-plane nitride-based semiconductor layer and the c-plane nitride-based semiconductor layer on the heat-treatment temperature.

FIG. 10A is a graph showing reflectance spectra when the heat treatment is conducted under different conditions on the Ag electrode having a thickness of 100 nm, which is formed on the m-plane nitride-based semiconductor layer, and FIG. 10B is a graph showing reflectance spectra when the heat treatment is conducted under different conditions on the Ag electrode having the thickness of 100 nm, which is formed on the c-plane nitride-based semiconductor layer.

FIG. 11 shows pictures of surface morphologies when the heat treatment is conducted under different conditions on the Ag electrodes each having a thickness of 100 nm, which are respectively formed on the m-plane nitride-based semiconductor layer and the c-plane nitride-based semiconductor layer.

FIG. 12A is a graph showing the relation between a reflectance of each of the Ag electrodes having a thickness of 100 nm, which are respectively formed on the m-plane nitride-based semiconductor layer and the c-plane nitride-based semiconductor layer, and the heat-treatment temperature, and FIG. 12B is a graph showing the relation between RMS surface roughness of each of the Ag electrodes having a thickness of 100 nm, which are respectively formed on the m-plane nitride-based semiconductor layer and the c-plane nitride-based semiconductor layer, and the heat-treatment temperature.

FIGS. 13A and 13B are graphs respectively showing the results of X-ray diffraction measurements of the Ag electrodes formed on the m-plane nitride-based semiconductor layer and the c-plane nitride-based semiconductor layer.

FIG. 14 is a graph showing the relation between a (111) plane/(200) plane X-ray diffraction integral intensity ratio of each of the Ag electrodes formed on the m-plane nitride-based semiconductor layer and the c-plane nitride-based semiconductor layer, and the heat-treatment temperature.

FIG. 15 shows pictures of the surface morphologies when the heat treatment is conducted under different conditions on the Ag electrodes each having a thickness of 400 nm, which are formed on the m-plane nitride-based semiconductor layer and the c-plane nitride-based semiconductor layer.

FIG. 16A is a graph showing the relation between a reflectance of each of the Ag electrodes having a thickness of 400 nm, which are respectively formed on the m-plane nitride-based semiconductor layer and the c-plane nitride-based semiconductor layer, and the heat-treatment temperature, and FIG. 16B is a graph showing the RMS surface roughness of each of the Ag electrodes having a thickness of 400 nm, which are respectively formed on the m-plane nitride-based semiconductor layer and the c-plane nitride-based semiconductor layer, and the heat-treatment temperature.

FIG. 17A is a graph showing the relation between the (111) plane/(200) plane X-ray diffraction integral intensity ratio of each of the Ag electrodes formed on the m-plane nitride-based semiconductor layer and the RMS surface roughness, and FIG. 17B is a graph showing the relation between the (111) plane/(200) plane X-ray diffraction integral intensity ratio of the Ag electrodes formed on the m-plane nitride-based semiconductor layer and the reflectance.

FIG. 18A is a graph showing the relation between the (111) plane/(200) plane X-ray diffraction integral intensity ratio of each of the Ag electrodes formed on the c-plane nitride-based semiconductor layer and the RMS surface roughness, and FIG. 18B is a graph showing the relation between the (111) plane/(200) plane X-ray diffraction integral intensity ratio of each of the Ag electrodes formed on the c-plane nitride-based semiconductor layer and the reflectance.

FIG. 19 is a graph showing the relation between the reflectance of the Ag electrode formed on the m-plane nitride-based semiconductor layer with respect to light having a light wavelength of 450 nm and a thickness of the Ag electrode.

FIG. 20 is a graph showing reflectance spectra when the Ag electrode having a thickness of 200 nm formed on the m-plane nitride-based semiconductor layer is subjected to the heat treatment under different conditions.

FIG. 21 is a sectional view illustrating a white light source according to another embodiment of the present disclosure.

FIG. 22 is a sectional view illustrating a structure of a protective layer 50.

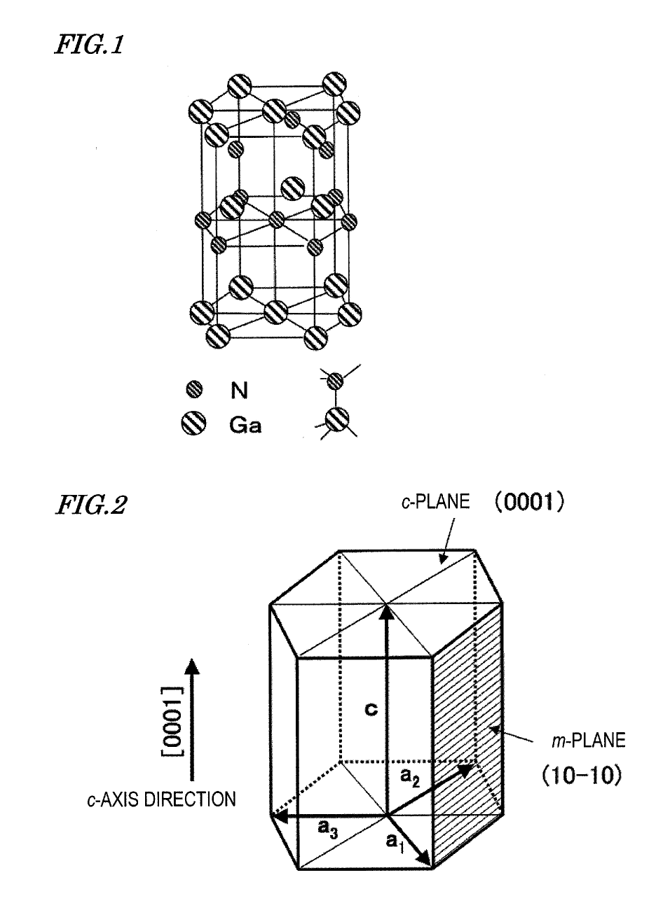

### DETAILED DESCRIPTION

A method for fabricating a nitride-based light-emitting device according to the present disclosure comprises: a step (a) of forming a nitride-based semiconductor multilayer structure including a p-type semiconductor region having an m-plane as a growing plane; and a step (b) of forming an Ag electrode so as to be in contact with the growing plane of the p-type semiconductor region, in which the step (b) includes: a step (b1) of forming the Ag electrode having a thickness in a range of 200 nm or more to 1,000 nm or less; and a step (b2) of heating the Ag electrode to a temperature in a range of 400° C. or more to 600° C. or less.

According to the embodiment, a reduction in reflectance due to the aggregation of Ag can be suppressed to realize the light-emitting device having high light-emitting efficiency and power efficiency.

In the exemplary embodiment, the Ag electrode is heated under an atmosphere with an oxygen partial pressure smaller than that of air in the step (b2).

In the exemplary embodiment, the Ag electrode is heated to the temperature in the range of 500° C. or more to 600° C. or less in the step (b2).

In the exemplary embodiment, the thickness of the Ag electrode is set in a range of 200 nm or more to 500 nm or less in the step (b1).

In the exemplary embodiment, the p-type semiconductor region includes a contact layer containing Mg at a concentration in a range of 4×10¹⁹ cm⁻³ or more to 2×10²⁰ cm⁻³ or less, and the contact layer is formed of an AlₓGa_{y}In_{z}N semiconductor having a thickness in a range of 26 nm or more to 60 nm or less, where x+y+z=1, x≧0, y>0, and z≧0.

In the exemplary embodiment, the method further includes a step (c) of forming a protective film on the Ag electrode after the step (b).

According to an exemplary embodiment of the present disclosure, a nitride-based semiconductor light-emitting device is fabricated by the method according to the exemplary embodiment of the present disclosure.

A nitride-based semiconductor light-emitting device according to the present disclosure includes: a nitride-based semiconductor multilayer structure including a p-type semiconductor region having an m-plane as a growing plane; and an Ag electrode provided so as to be in contact with the growing plane of the p-type semiconductor region, in which the Ag electrode has a thickness in a range of 200 nm or more to 1,000 nm or less, and an integral intensity ratio of X-ray intensities on a (111) plane and on a (200) plane on the growing plane of the Ag electrode is in a range of 20 or more to 100 or less.

Another nitride-based semiconductor light-emitting device according to the present disclosure includes: a nitride-based semiconductor multilayer structure including a p-type semiconductor region having an m-plane as a growing plane; and an Ag electrode provided so as to be in contact with the growing plane of the p-type semiconductor region, in which the Ag electrode has a thickness in a range of 200 nm or more to 1,000 nm or less, and a peak intensity ratio of X-ray intensities on a (111) plane and on a (200) plane on the growing plane of the Ag electrode is in a range of 30 or more to 150 or less.

In the still another exemplary embodiment, the Ag electrode is subjected to heat treatment under an atmosphere with an oxygen partial pressure smaller than that of air.

In the still another exemplary embodiment, the Ag electrode has a thickness a range of 200 nm or more to 500 nm or less.

In the still another exemplary embodiment, the p-type semiconductor region includes a contact layer containing Mg at a concentration in a range of 4×10¹⁹ cm⁻³ or more to 2×10²⁰ cm⁻³ or less, and the contact layer is formed of an AlₓGa_{y}In_{z}N semiconductor having a thickness in a range of 26 nm or more to 60 nm or less, where x+y+z=1, x≧0, y>0, and z≧0.

In the still another exemplary embodiment, the contact layer contains Mg at a concentration in a range of 4×10¹⁹ cm⁻³ or more to 2×10²⁰ cm⁻³ or less and has a thickness in a range of 30 nm or more to 45 nm or less.

In the still another exemplary embodiment, the nitride-based semiconductor light-emitting device further includes a protective film formed on the Ag electrode.

A light source according to the present disclosure includes: a nitride-based semiconductor light-emitting device; and a wavelength conversion section containing a fluorescent substance for converting a wavelength of light emitted from the nitride-based semiconductor light-emitting device, in which the nitride-based semiconductor light-emitting device includes: a nitride-based semiconductor multilayer structure including a p-type semiconductor region having an m-plane as a growing plane; and an Ag electrode provided so as to be in contact with the growing plane of the p-type semiconductor region, and the Ag electrode has a thickness in a range of 200 nm or more to 1,000 nm or less, and an integral intensity ratio of X-ray intensities on a (111) plane and on a (200) plane on the growing plane of the Ag electrode is in a range of 20 or more to 100 or less.

According to the present disclosure, the thickness of the p-side Ag electrode provided on the p-type semiconductor region is set to 200 nm or more, and the heat treatment therefor is conducted in the temperature range of 400° C. or more to 600° C. or less. As a result, a reduction in reflectance due to the aggregation of Ag can be suppressed to realize the light-emitting device having high light-emitting efficiency and power efficiency.

In the still another exemplary embodiment, the Ag electrode is subjected to heat treatment under an atmosphere with an oxygen partial pressure smaller than that of air.

### First Embodiment

Hereinafter, a nitride-based semiconductor light-emitting device according to an exemplary embodiment of the present disclosure is described with reference to the accompanying drawings. In the drawings, any elements illustrated in multiple drawings and having substantially the same function are denoted by the same reference numeral for the sake of simplicity. It should be noted, however, that the present disclosure is in no way limited to the specific exemplary embodiments to be described below.

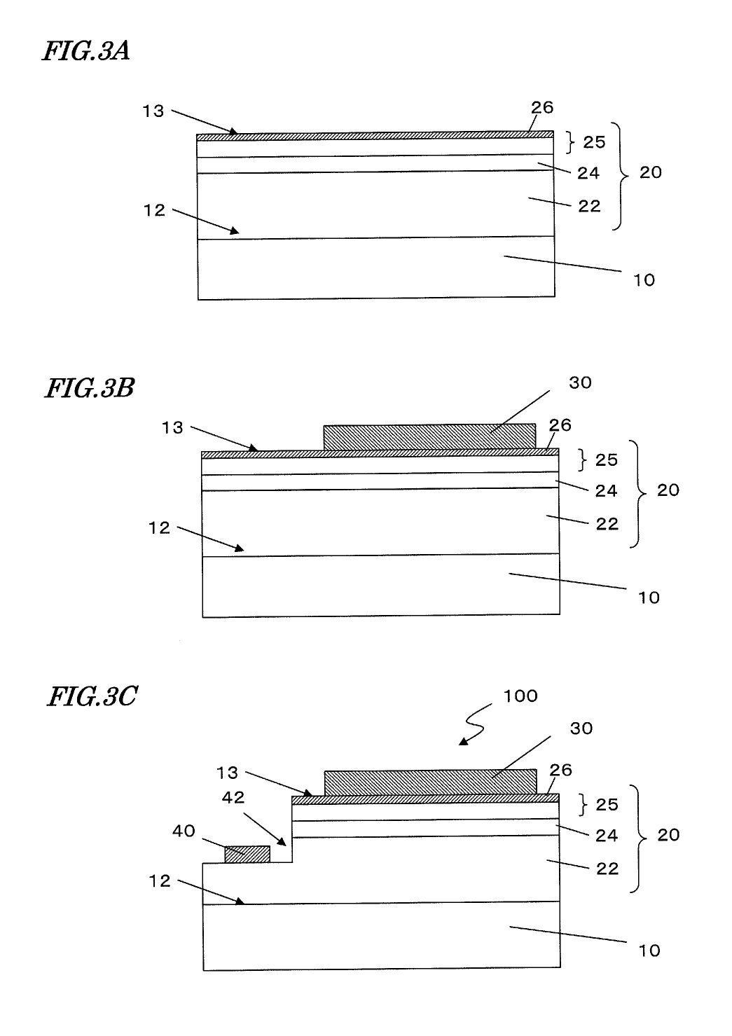

First, a method for fabricating a nitride-based semiconductor light-emitting device 100 according to this embodiment is described. First, as illustrated in FIG. 3A, a substrate 10 is prepared. On the substrate 10, a semiconductor multilayer structure 20 with a growing plane being an m-plane is formed. As the semiconductor multilayer structure 20, an n-type AlᵤGaᵥIn_{w}N layer 22, an active layer 24, and a p-type Al_{d}GaₑN layer 25 are formed. Although the semiconductor multilayer structure 20 is formed on the substrate 10 in a wafer state in practice, only a part of the wafer, which corresponds to a chip region (region which becomes a chip by subsequent division), is illustrated in FIG. 3A.

Next, as illustrated in FIG. 3B, an Ag electrode 30 having a thickness of 200 nm or more to 1,000 nm or less is formed so as to be in contact with a growing plane 13 of the p-type Al_{d}GaₑN layer 25. The Ag electrode 30 is formed by, for example, vapor deposition of an Ag layer under a normal temperature and then using a lift-off process.

Then, the Ag electrode 30 is heated to a temperature of 400° C. or more to 600° C. or less.

Thereafter, as illustrated in FIG. 3C, a recess 42 is formed. In the recess 42, an n-electrode 40, which is held in contact with the n-type AlᵤGaᵥIn_{w}N layer 22, is formed. Thereafter, by dicing, the nitride-based semiconductor light-emitting device 100 is obtained.

According to the fabrication method of this embodiment, by performing heat treatment at a temperature of 400° C. or more to 600° C. or less on the Ag electrode 30, contact resistance between the Ag electrode 30 and the p-type Al_{d}GaₑN layer 25 can be reduced.

The inventor of the present disclosure found the following. When the Ag layer is formed on the p-type Al_{d}GaₑN layer 25 having the m-plane as the growing plane and the heat treatment is then performed, the aggregation in the Ag layer occurs in a mode different from that in the case where the Ag layer is formed on a c-plane. When the Ag electrode 30 is formed on the m-plane, the development of aggregation of Ag can be suppressed even if the heat treatment is performed by setting a thickness of the Ag electrode 30 to 200 nm or more. Therefore, a reflectance of light from the active layer 24 can be kept high.

In order to suppress the effects due to the aggregation of Ag, the thickness of the Ag electrode 30 may be set to 200 nm or more. In view of the formation of a protective layer on the Ag electrode 30, however, the thickness of the Ag electrode 30 is desired to be within a certain range or less. In general, when Ag is used for the electrode, the protective layer is formed on the Ag electrode in order to prevent oxidation, sulfuration, and chloridation of Ag so as to prevent the migration and the generation of a leak current during energization. If the thickness of the Ag electrode is too large, a gap is generated between the protective layer and the Ag electrode at an end of the Ag electrode to bring about the possibility of generation of a crack in a part of the protective layer, which may cause a reduction of lifetime of the Ag electrode. In order to prevent the problems described above, the thickness of the Ag electrode 30 is required to be set within the certain range or less. A thickness of the Ag electrode 30 is desirably 1,000 nm or less, more desirably, 500 nm or less.

According to the fabrication method of this embodiment, the aggregation in the Ag electrode 30 is suppressed to keep the reflectance of light from the active layer 24 high. The aggregation in the Ag electrode 30 has a correlation with plane orientation of Ag crystal. As a result of examination by the inventor of the present disclosure, when an integral intensity ratio of X-ray intensities on a (111) plane and a (200) plane, which are obtained by an X-ray diffraction measurement, is in the range of 20 or more to 100 or less, an increase in surface roughness of the Ag electrode 30 can be suppressed to enable the reflectance of light to be kept high. In the case of the definition with a peak intensity ratio in place of the integral intensity ratio, when the peak intensity ratio is in the range of 30 or more to 150 or less, the same effects can be obtained.

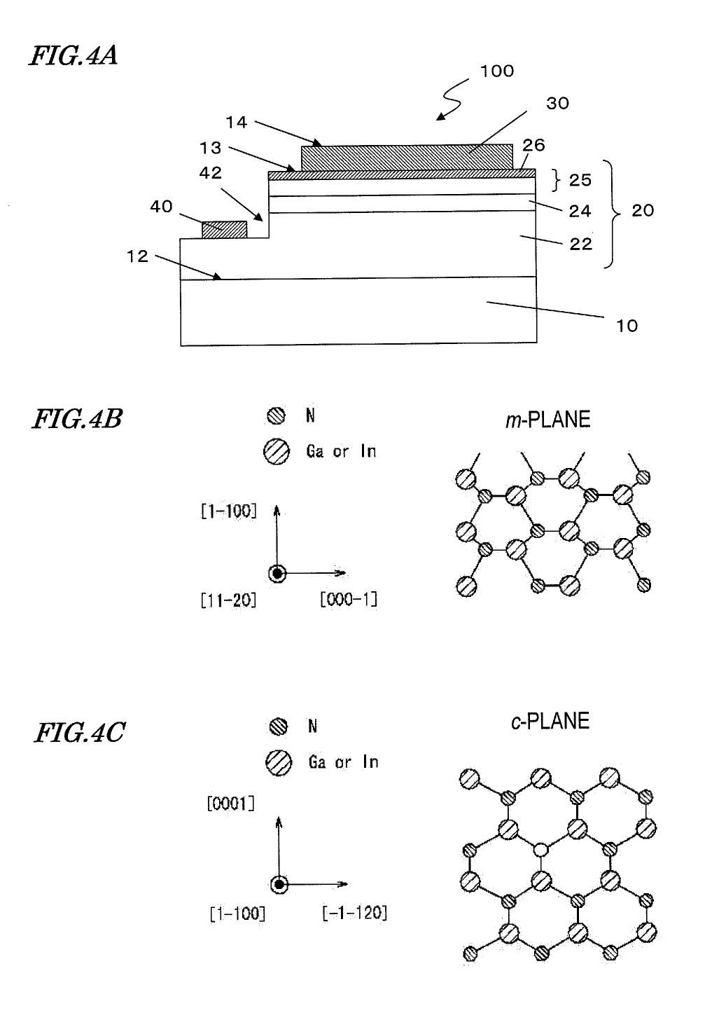

Next, a specific structure of the nitride-based semiconductor light-emitting device 100 is described referring to FIG. 4A.

FIG. 4A schematically illustrates the cross-sectional structure of the nitride-based semiconductor light-emitting device 100 according to the embodiment of the present disclosure. The nitride-based semiconductor light-emitting device 100 illustrated in FIG. 4A is a semiconductor device made of GaN-based semiconductors and has the nitride-based semiconductor multilayer structure 20.

The nitride-based semiconductor light-emitting device 100 of this embodiment includes the substrate 10 formed of a GaN-based semiconductor, which has an m-plane as the growing surface 12, the semiconductor multilayer structure 20 that has been formed on the substrate 10, and the Ag electrode 30 formed on the semiconductor multilayer structure 20. In this embodiment, the semiconductor multilayer structure 20 is a semiconductor multilayer structure that has been formed through an m-plane crystal growth and its growing plane 13 is an m-plane. It should be noted, however, that a-plane GaN could grow on an r-plane sapphire substrate in some instances. That is why depending on the growth conditions, the growing surface of the substrate 10 does not always have to be an m-plane. In the semiconductor multilayer structure 20 of this embodiment, at least the surface of its p-type semiconductor region that is in contact with an electrode needs to be an m-plane.

The nitride-based semiconductor light-emitting device 100 of this embodiment includes the substrate 10 for supporting the semiconductor multilayer structure 20. However, the nitride-based semiconductor light-emitting device 100 may have any other substrate instead of the substrate 10 and may also be used without the substrate.

FIG. 4B schematically illustrates the crystal structure of a nitride-based semiconductor, which has an m-plane as the growing surface, as viewed on a cross section thereof (that intersects with the principal surface of the substrate at right angles). Ga atoms and nitrogen atoms are present on the same atomic-plane that is parallel to the m-plane, and hence no electrical polarization is produced perpendicularly to the m-plane. That is to say, the m-plane is a non-polar plane and no piezoelectric field is produced in an active layer that grows perpendicularly to the m-plane. It should be noted that In and Al atoms that have been added are located at Ga sites and replace the Ga atoms. Even if at least some of the Ga atoms are replaced with those In or Al atoms, no electrical polarization is still produced perpendicularly to the m-plane.

Such a GaN-based substrate, which has an m-plane as the growing surface, is referred to herein as an “m-plane GaN-based substrate”. To obtain an m-plane nitride-based semiconductor multilayer structure that has grown perpendicularly to the m-plane, typically such an m-plane GaN substrate may be used and semiconductors may be grown on the m-plane of that substrate, because the plane orientation of the GaN-based substrate is reflected on the plane orientation of the semiconductor multilayer structure. However, the growing surface of the substrate does not have to be an m-plane as described above, and the device as a final product may already have its substrate removed.

The crystal structure of a nitride-based semiconductor, which has a c-plane as the growing surface, as viewed on a cross section thereof (that intersects with the principal surface of the substrate at right angles) is illustrated schematically in FIG. 4C just for a reference. Ga atoms and nitrogen atoms are not present on the same atomic-plane that is parallel to the c-plane, and therefore, electrical polarization is produced perpendicularly to the c-plane. Such a GaN-based substrate, which has a c-plane as the growing surface, is referred to herein as a “c-plane GaN-based substrate”.

A c-plane GaN-based substrate is generally used to grow GaN-based semiconductor crystals thereon. In such a substrate, a Ga atom layer and a nitrogen atom layer that extend parallel to the c-plane are slightly misaligned from each other in the c-axis direction, and therefore, electrical polarization is produced in the c-axis direction.

Referring to FIG. 4A again, on the growing surface (m-plane) 12 of the substrate 10, the semiconductor multilayer structure 20 is formed. The semiconductor multilayer structure 20 includes the active layer 24 including an AlₐIn_{b}Ga_{c}N layer (where a+b+c=1, a≧0, b≧0 and c≧0), and the Al_{d}GaₑN layer (where d+e=1, d≧0 and e≧0) 25, which is located on the other side of the active layer 24 opposite to the growing surface (m-plane) 12. In this embodiment, the active layer 24 is an electron injection region of the nitride-based semiconductor light-emitting device 100.

The active layer 24 of this embodiment has a GaInN/GaN multi-quantum well (MQW) structure (with a thickness of 81 nm, for example) in which Ga_{0.9}In_{0.1}N well layers (each having a thickness of 9 nm, for example) and GaN barrier layers (each having a thickness of 9 nm, for example) are alternately stacked one upon another.

On the active layer 24, the p-type Al_{d}GaₑN layer 25 is formed. A thickness of the p-type Al_{d}GaₑN layer 25 is, for example, 0.2 to 2 μm. An undoped GaN layer may be inserted between the active layer 24 and the p-type Al_{d}GaₑN layer 25.

The semiconductor multilayer structure 20 also includes other layers. Between the active layer 24 and the substrate 10, the AlᵤGaᵥIn_{w}N layer (where u+v+w=1, u≧0, v≧0, and w≧0) 22 is formed. The AlᵤGaᵥIn_{w}N layer 22 of this embodiment is a first-conductivity type (n-type) AlᵤGaᵥIn_{w}N layer 22.

In the p-type Al_{d}GaₑN layer 25, a composition ratio d of Al is not required to be uniform in a thickness direction. In the p-type Al_{d}GaₑN layer 25, the composition ratio d of Al may vary continuously or in a stepwise manner in the thickness direction. Specifically, the p-type Al_{d}GaₑN layer 25 may have a multi-layered structure in which a plurality of layers having different Al composition ratios d are stacked. Moreover, a concentration of a dopant may vary in the thickness direction in the p-type Al_{d}GaₑN layer 25.

In the vicinity of the uppermost surface of the p-type Al_{d}GaₑN layer 25, a p-type contact layer 26 made of p-type Al_{d}GaₑN is formed. A thickness of a region of the p-type Al_{d}GaₑN layer 25 excluding the p-type contact layer 26 is, for example, 10 nm or more to 500 nm or less. An Mg concentration in the region is 1×10¹⁸ cm⁻³ or more to 1×10^{19 cm}⁻³ or less, for example. The p-type contact layer 26 has a higher Mg concentration than that of the region of the p-type Al_{d}GaₑN layer 25 excluding the p-type contact layer 26. The high-concentration Mg in the p-type contact layer 26 effectively acts in terms of promotion of diffusion of Ga. When the region of the p-type Al_{d}GaₑN layer 25 excluding the p-type contact layer 26 is provided so as to have a thickness of 100 nm or more to 500 nm or less, the diffusion of Mg toward the active layer 24 can be suppressed even if Mg is contained in the p-type contact layer 26 at a high concentration. The Mg concentration of the p-type contact layer 26 may be, for example, from 4×10¹⁹ cm⁻³ or more to 2×10²⁰ cm⁻³ or less. If the concentration of Mg in the p-type contact layer 26 is lower than 4×10¹⁹ cm⁻³, the contact resistance cannot be sufficiently lowered. On the other hand, if the concentration of Mg in the p-type contact layer 26 exceeds 2×10²⁰ cm⁻³, the bulk resistance of the p-type contact layer 26 more remarkably increases.

The thickness of the p-type contact layer 26 may be 26 nm or more to 60 nm or less. If a thickness of the p-type contact layer 26 is smaller than 26 nm, the contact resistance cannot be sufficiently lowered. If the thickness of the p-type contact layer 26 is 30 nm or more, the contact resistance can be further lowered. On the other hand, if the thickness of the p-type contact layer 26 exceeds 45 nm, the bulk resistance of the p-type contact layer 26 starts increasing. When the thickness of the p-type contact layer 26 exceeds 60 nm, the bulk resistance of the p-type contact layer 26 more remarkably increases. When both the Mg concentration and the thickness of the p-type contact layer 26 respectively fall within the above-mentioned ranges, the contact resistance can be sufficiently lowered. For example, when the thickness of the p-type contact layer 26 is 10 nm even if the Mg concentration is from 4×10¹⁹ cm⁻³ or more to 2×10²⁰ cm⁻³ or less, the contact resistance is not sufficiently lowered.

The p-type Al_{d}GaₑN layer 25 may be doped with, for example, Zn, Be or the like, as a p-type dopant other than Mg.

In view of the reduction of the contact resistance, the uppermost portion of the p-type Al_{d}GaₑN layer 25 (upper surface portion of the semiconductor multilayer structure 20) may include a layer whose composition ratio d of Al is zero (GaN layer). The Al composition ratio d may be other than zero. For example, for the p-type contact layer 26, Al_{0.05}Ga_{0.95}N with the Al composition ratio d being set to about 0.05 can be used.

On the semiconductor multilayer structure 20, the Ag electrode 30 is formed. In this embodiment, the p-electrode is the Ag electrode 30 having a thickness of 200 nm or more to 1,000 nm or less. A thickness of the Ag electrode 30 is obtained by, for example, a cross-sectional scanning electron microscope (SEM) or cross-sectional transmission electron microscope (TEM) measurement. In this embodiment, the Ag electrode 30 is held in contact with the p-type contact layer 26. The Ag electrode 30 is a layer containing Ag as a main component. Although the Ag electrode 30 may contain a substance other than Ag, a ratio of the number of atoms of the substance other than Ag to the entire Ag layer is 5% or lower. As impurities contained in the Ag electrode 30, for example, Ga or Mg contained in the semiconductor multilayer structure 20 is considered. Besides, Zn or In may be added to the Ag electrode 30. When the Ag electrode is formed by a common electron beam evaporation process, there is a possibility that the impurities such as a light element unintentionally get mixed therein. By setting the ratio of the number of atoms of the impurities to the entire Ag layer to 1% or lower, the reflectance can be improved. Moreover, by setting the ratio of the number of atoms of the impurities to the entire Ag layer to 0.1% or lower, the reflectance can be further improved. A growing plane 14 of the Ag electrode 30 is a plane opposite to that of the Ag electrode 30, which is held in contact with the p-type contact layer 26.

A thickness of the substrate 10 having the m-plane as the growing plane 12 is, for example, 100 or more to 400 μm or less. This range is set because the handling of the wafer is not adversely affected if the thickness of the substrate 10 is about 100 μm or more. The substrate 10 of this embodiment may have a multilayer structure as long as the growing plane 12 is the m-plane made of a GaN-based material. Specifically, the substrate 10 of this embodiment includes a substrate at least having the m-plane as the growing plane 12. Therefore, the entire substrate may be a GaN-based one or made of the combination with another material.

In the configuration according to this embodiment, an n-electrode (n-type electrode) 40 is formed on a part of the n-type AlᵤGaᵥIn_{w}N layer 22 (having a thickness of 0.2 to 2 μm, for example) on the substrate 10. In the example illustrated in FIG. 4A, the recess 42 is formed on the region of the semiconductor multilayer structure 20, on which the n-electrode 40 is formed, so that a part of the n-type AlᵤGaᵥIn_{w}N layer 22 is exposed. The n-electrode 40 is provided on the surface of the part of the n-type AlᵤGaᵥIn_{w}N layer 22 exposed in the recess 42. The n-electrode 40 is formed to have a multilayer structure of, for example, a Ti layer, an Al layer, and a Pt layer. A thickness of the n-electrode 40 is, for example, 100 to 200 nm.

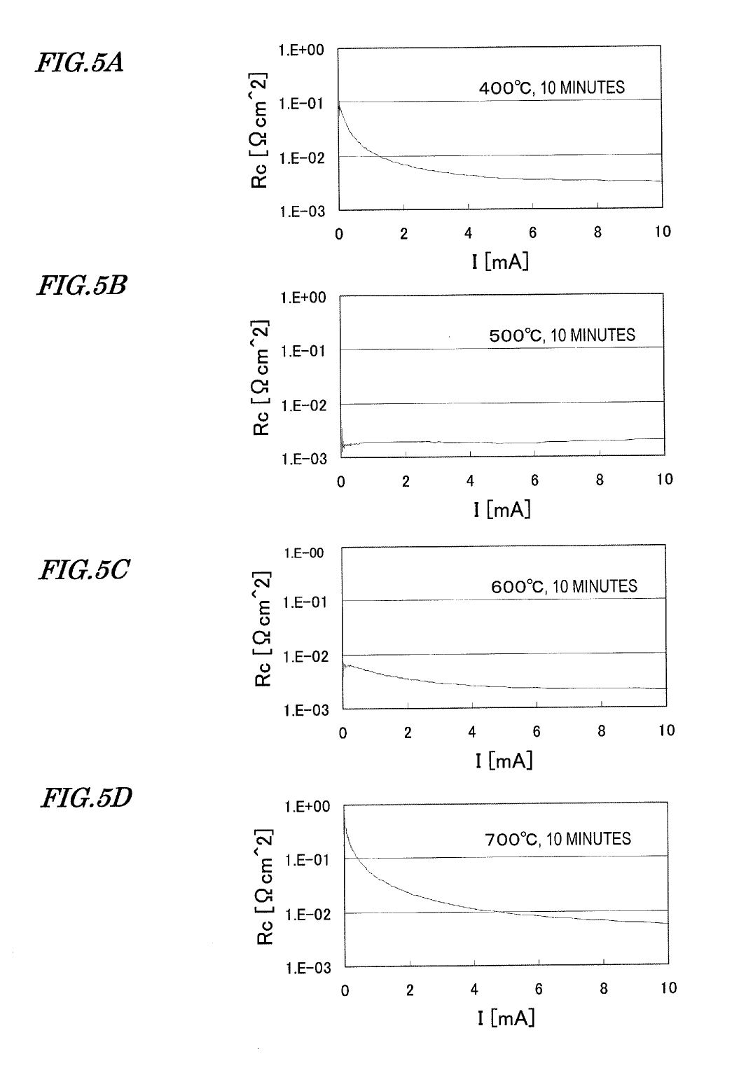

Next, referring to FIGS. 5A to 20, the features of this embodiment are described in further detail.

First, the Ag electrode 30 having a thickness of 400 nm is formed on the p-type Al_{d}GaₑN layer 25 including the p-type contact layer 26. The relation between the contact resistance of the Ag electrode 30 and the heat-treatment conditions is described.

FIGS. 5A to 5D show the results of evaluation of the contact resistance of the Ag electrode 30 by using a transmission line method (TLM). The electrode 30 was formed at a thickness of 400 nm on the p-type Al_{d}GaₑN layer 25 including the p-type contact layer 26. The measurements in this embodiment were conducted by using samples, each including the p-type Al_{d}GaₑN layer 25 having a thickness of 1.5 μm to 2.0 μm and the Mg concentration of 0.8×10¹⁹ to 1.0×10¹⁹ cm⁻³, and the p-type contact layer 26 having a thickness of 40 nm and the Mg concentration of 5.0×10¹⁹ cm⁻³.

With a TLM pattern used in this embodiment, a plurality of electrodes, each being 100 μm×200 μm in size, were arranged at intervals of 8 μm, 12 μm, 16 μm, and 20 μm. From electric characteristics of the plurality of electrodes, the contact resistance was estimated. A horizontal axis indicates a current value at the time of measurement, whereas a vertical axis indicates a value of the contact resistance obtained at the time of application of each current. FIG. 5A shows the result obtained when the heat-treatment temperature was 400° C., FIG. 5B shows the result at 500° C., FIG. 5C shows the result at 600° C., and FIG. 5D shows the result at 700° C. The heat treatment was conducted in a nitrogen atmosphere, and heat-treatment time was about 10 minutes for all the samples. The heat-treatment time and the atmosphere are not particularly limited, and may be appropriately determined. A value “1.0E−01” on the vertical axis means “1.0×10⁻¹”, and “1.0E−02” means “1.0×10⁻²”. In other words, “1.0E+X” means “1.0×10^{X}”.

In general, the contact resistance is inversely proportional to an area S (cm²) of a contact. Here, the relation R=Rc/S is established, where R(Ω) denotes the contact resistance. A proportionality constant Rc is referred to as specific contact resistance and corresponds to the contact resistance R obtained when the contact area S is 1 cm². Specifically, the magnitude of the specific contact resistance serves as an index for evaluating contact characteristics without depending on the contact area S. Hereinafter, the “specific contact resistance” is sometimes abbreviated as the “contact resistance”.

As shown in FIGS. 5A to 5D, a characteristic of Ohmic contact which shows an approximately constant resistance value with respect to a current value under a condition of the heat-treatment temperature of 500° C. was obtained. Further, the contact resistance value became lowest under the condition of the heat-treatment temperature of 500° C. For example, the contact resistance value at the current value of 2 mA was 2.0×10⁻³ Ωcm². On the other hand, when the heat-treatment temperature was 400° C. or 700° C., the contact resistance value was not constant with respect to the current value and therefore, Schottky contact occurred. The contact resistance values at the current value of 2 mA were 6.9×10⁻³ Ωcm² at 400° C., 3.5×10⁻³ Ωcm² at 600° C., and 2.2×10⁻² Ωcm² at 700° C., which show that the contact resistance is reduced when the heat temperature is conducted at 500° C. to 600° C.

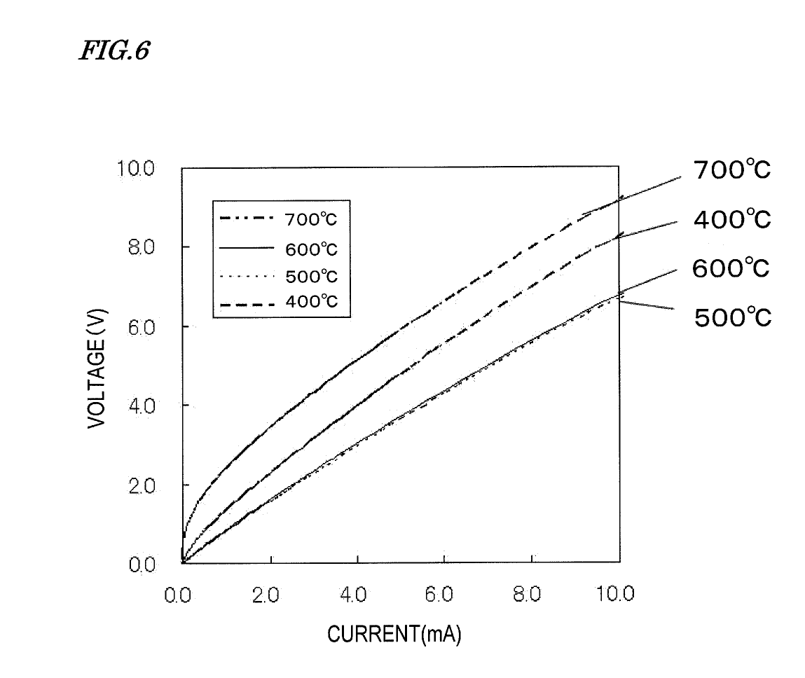

FIG. 6 shows current-voltage characteristics at the respective heat-treatment temperatures when the interval between the electrodes is 12 μm. An Ohmic contact (V=IR) was obtained under the condition of the heat-treatment temperature of 500° C. to 600° C. On the other hand, non-linear curves were obtained under the conditions of 400° C. and 700° C., which show the occurrence of Shottky contact.

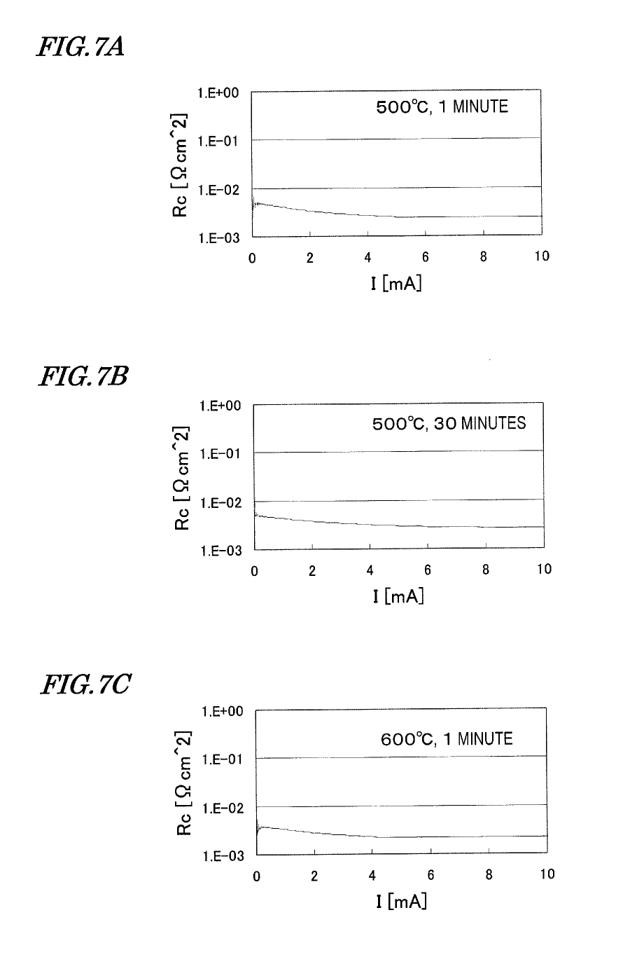

Next, the results obtained when the heat-treatment time and the temperature were varied based on the heat-treatment condition of 500° C. at which the lowest contact resistance value was obtained are shown in FIGS. 7A to 7D.

When the heat-treatment time was varied to one minute (FIG. 7A) and 30 minutes (FIG. 7B) with the heat-treatment temperature fixed to 500° C., relatively low contact values, that is, 3.4×10⁻³ Ωcm² and 3.8×10⁻³ Ωcm² were respectively obtained at the current value of 2 mA. Even when the heat-treatment temperature was set to 600° C. and the heat-treatment time was set to one minute (FIG. 7C), the contact resistance value was as low as 2.8×10⁻³ Ωcm² (at the current value of 2 mA).

As described above, in the nitride-based semiconductor light-emitting device with the m-plane being the growing plane according to this embodiment, the contact resistance of the Ag electrode 30 formed on the p-type Al_{d}GaₑN layer 25 including the p-type contact layer 26 varies depending on the heat-treatment conditions. When the heat-treatment temperature is 400° C. or more to 600° C. or less, the value of the contact resistance can be sufficiently lowered to realize the Ohmic contact. When the heat-treatment temperature is 500° C. or more to 600° C. or less, a lower value of the contact resistance can be obtained.

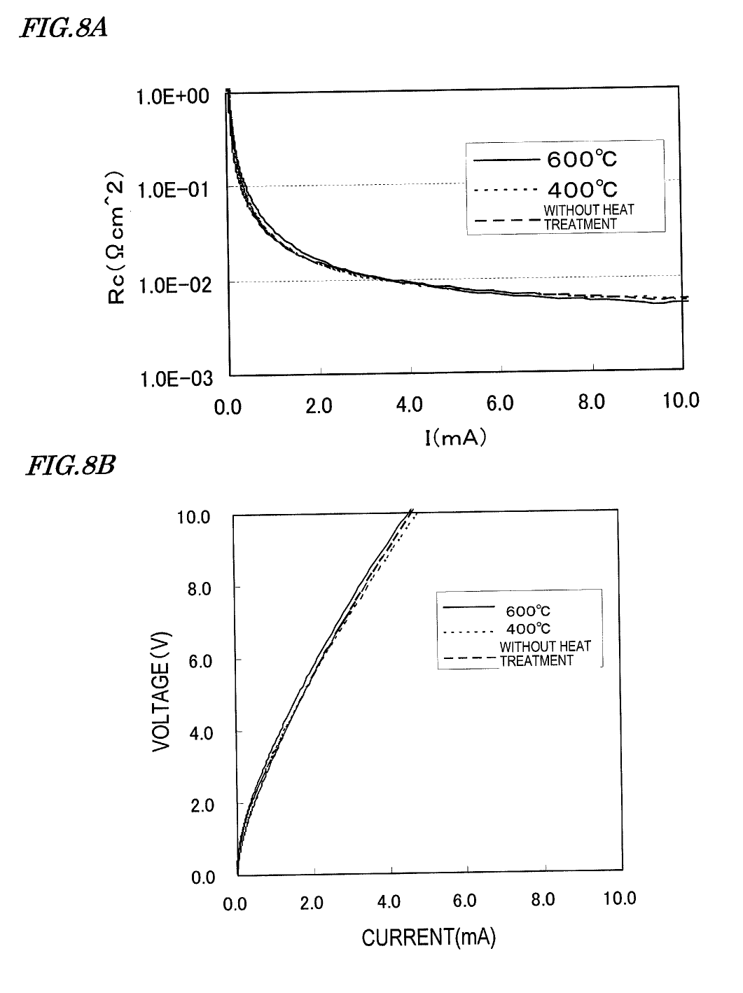

For comparison, FIGS. 8A and 8B show the results of experiments on samples, each including the Ag electrode having the same thickness (400 nm) as that of the samples used for the measurements shown in FIGS. 5A to 5D, and 6, which was formed on a c-plane nitride-based semiconductor layer. FIG. 8A shows the dependence of the contact resistance on a current value, and FIG. 8B shows a current-voltage characteristic obtained when the interval between the electrodes was 12 μm. The heat treatment was conducted in the nitrogen atmosphere, and the heat-treatment time was about 10 minutes for all the samples.

FIG. 8A shows that the contact resistance value (at the current value of 2 mA) of each of the sample without the heat treatment, the sample subjected to the heat treatment at 400° C., and the sample subjected to the heat treatment at 600° C. was 1.4 to 1.6×10⁻² Ωcm². As shown in FIGS. 5A to 5D, and 6, the contact resistance of the Ag electrode 30 of this embodiment greatly varied depending on the heat-treatment temperature, whereas the Ag electrode formed on the c-plane nitride-based semiconductor layer under the same conditions had smaller dependence on the heat-treatment temperature. Specifically, it was found that the change in contact resistance of the Ag electrode with respect to the heat-treatment temperature greatly differs between the case where the Ag electrode is formed on the m-plane nitride-based semiconductor layer and the case where the Ag electrode is formed on the conventional c-plane nitride-based semiconductor layer.

In comparison between the current-voltage characteristic shown in FIG. 8B and the result (FIG. 6) on the Ag electrode 30 formed on the m-plane nitride-based semiconductor layer described above, the Ag electrode formed on the c-plane nitride-based semiconductor layer has little heat-treatment temperature dependence and forms the Shottoky contact.

As shown in FIGS. 8A and 8B, when the Ag layer having a high reflectance is directly formed as the p-electrode on the c-plane nitride-based semiconductor layer, the contact resistance cannot be sufficiently lowered. For example, in Japanese Patent Application Laid-open No. 2005-197687, the contact resistance is successfully reduced by inserting a metal layer of Ni or the like between the p-type contact layer of the c-plane nitride semiconductor device and the Ag electrode.

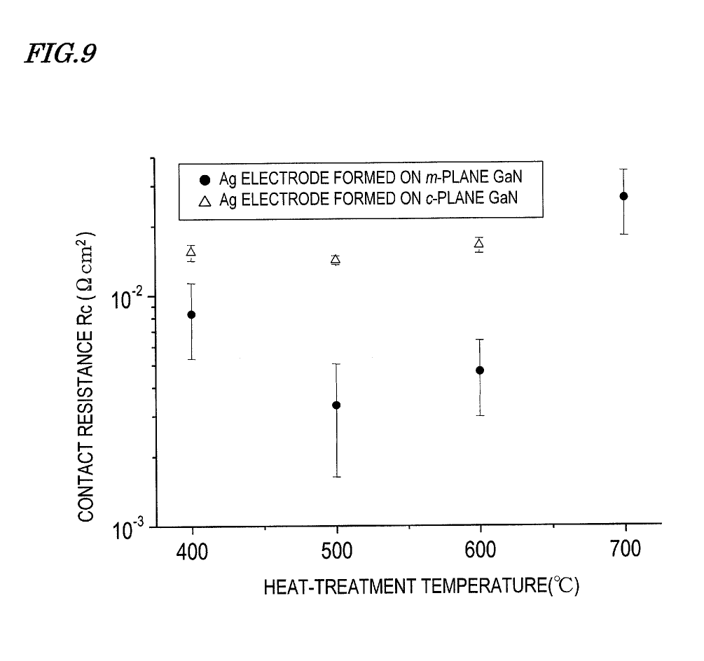

FIG. 9 shows the summary of the results of the relation between the contact resistances of the Ag electrodes 30 respectively formed on the m-plane nitride-based semiconductor layer and the c-plane nitride-based semiconductor layer, and the heat-treatment temperature. As the value of the contact resistance, the value obtained at the current value of 2 mA is plotted. The results shown in FIGS. 5A to 5D are used as the contact resistance of the Ag electrode formed on the m-plane nitride-based semiconductor layer, whereas the result shown in FIG. 8A is used as the contact resistance of the Ag electrode formed on the c-plane nitride-based semiconductor layer.

As shown in FIG. 9, it is apparent that the relation of the contact resistance of the Ag electrode 30 formed on the m-plane nitride-based semiconductor layer according to this embodiment and the heat-treatment temperature is different from the result obtained with the Ag electrode formed on the conventional c-plane nitride-based semiconductor layer. It is understood that the low contact resistance can be realized by performing the heat treatment on the Ag electrode 30 formed on the m-plane nitride-based semiconductor layer.

From the results described above, it is understood that sufficiently low contact resistance can be obtained by performing the heat treatment at a temperature of 400° C. to 600° C. on the Ag electrode 30 formed on the m-plane nitride semiconductor device. It is also understood that the lower contact resistance can be obtained by performing the heat treatment at a temperature of 500° C. or more to 600° C. or less. Moreover, it becomes clear that the above-mentioned phenomenon is unique to the m-plane nitride-based semiconductor device, which is not found with the conventional c-plane nitride-based semiconductor device.

The inventor of the present disclosure considers that the contact resistance of the Ag electrode 30 can be further reduced by optimizing the Mg concentration and the thickness of the p-type contact layer 26 in the m-plane nitride-based semiconductor device. As described above, in the p-type Al_{d}GaₑN layer 25 of this embodiment, the concentration of Mg corresponding to a p-type dopant is changed so as to be different in the p-type contact layer 26 and in the region other than the p-type contact layer 26. For example, the p-type Al_{d}GaₑN layer 25 is doped with Mg at a concentration of 1×10¹⁸ cm⁻³ or more to 1×10¹⁹ cm⁻³ or less, and the p-type contact layer 26 is doped with Mg at a concentration of 4×10¹⁹ cm⁻³ or more to 2×10²⁰ cm⁻³ or less. A thickness of the p-type contact layer 26 is, for example, 26 nm or more to 60 nm or less. The low contact resistance can be realized by appropriately controlling the Mg concentration and the thickness of each of the p-type Al_{d}GaₑN layer 25 and the p-type contact layer 26 in the manner described above.

Next, the relation between the Ag aggregation phenomenon, the reflectance, and the heat-treatment conditions is described.

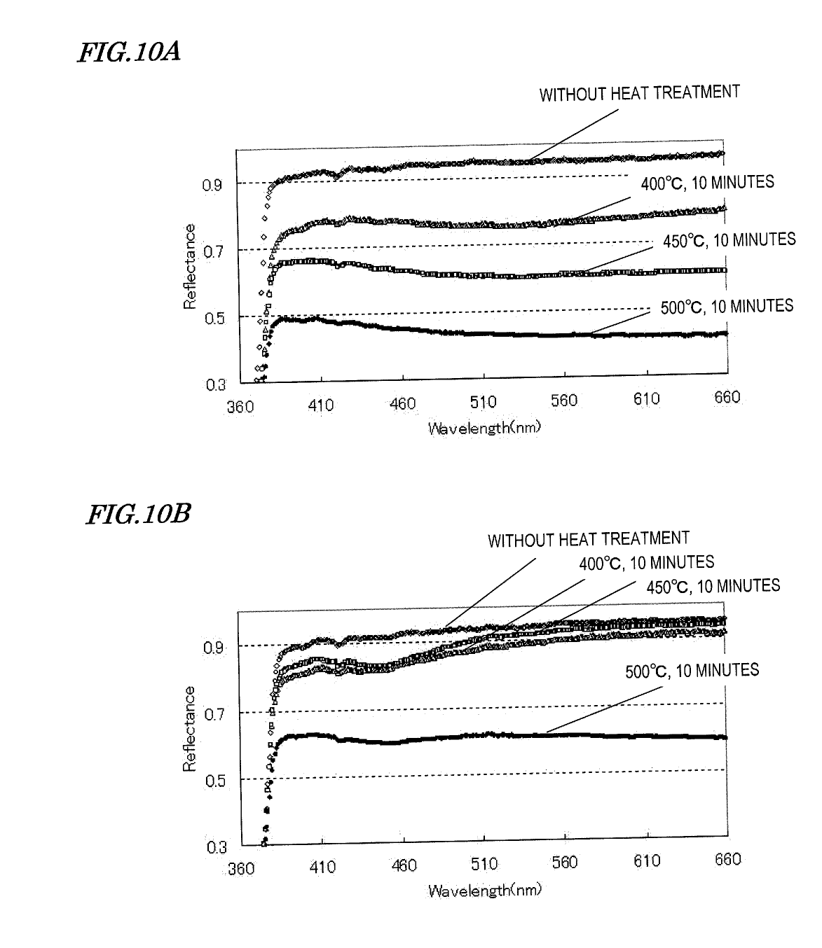

FIGS. 10A and 10B show the dependence (results of experiments) of the reflectance of the Ag electrode 30 formed on the p-type Al_{d}GaₑN layer 25 including the p-type contact layer 26 on the heat-treatment temperature. The thickness of the Ag electrode 30 was uniformly set to 100 nm, the thickness of the p-type contact layer 26 was set to 40 nm, and the thickness of the p-type Al_{d}GaₑN layer 25 was set to 1.5 to 2.0 μm. For comparison, the result of experiment on the sample including the Ag electrode having the same thickness formed on the c-plane nitride-based semiconductor layer is also shown. FIG. 10A shows reflectance spectra of the Ag electrodes, each formed on the m-plane nitride-based semiconductor layer according to this embodiment, and FIG. 10B shows reflectance spectra of the Ag electrodes, each formed on the c-plane nitride-based semiconductor layer. The heat treatment was conducted in the nitride atmosphere, and the heat-treatment time was about 10 minutes for all the samples. For the measurement of the reflectance, a V-570 type UV-visible near infrared spectrophotometer and an ARV-475S-type absolute spectral diffuse reflectance measurement device (manufactured by JASCO Corporation) were used. Light was incident from the semiconductor layer side, and the reflectance in the vicinity of an interface between the p-type contact layer 26 and the Ag electrode 30 was measured.

As shown in FIGS. 10A and 10B, the reflectance suddenly dropped in the vicinity of a wavelength of 360 nm. The reflectances described in this specification all correspond to the results of measurements obtained when the light is incident from the semiconductor layer side. Therefore, the reflectance suddenly drops at the wavelength of 360 nm due to the absorption by the GaN layer corresponding to an underlayer for the Ag layer. When the heat-treatment temperature was relatively low, that is, 400° C. or lower, a high reflectance of about 80% was obtained in a visible-light region at the wavelength of 360 nm or longer. However, when the heat-treatment temperature exceeded 450° C., the reflectance started decreasing. As the result of the comparison between the reflectance on the c-plane and the reflectance on the m-plane, the reflectance is more remarkably lowered for the Ag electrode on the m-plane due to the heat treatment although the tendencies are similar to each other. For example, in the case of the Ag electrode formed on the c-plane shown in FIG. 10B, even the sample which was subjected to the heat treatment at 450° C. exhibited a reflectance as high as about 80%. On the other hand, in the case of the Ag electrode formed on the m-plane shown in FIG. 10A, the sample which was subject to the same heat treatment exhibited a low reflectance of 70% or lower.

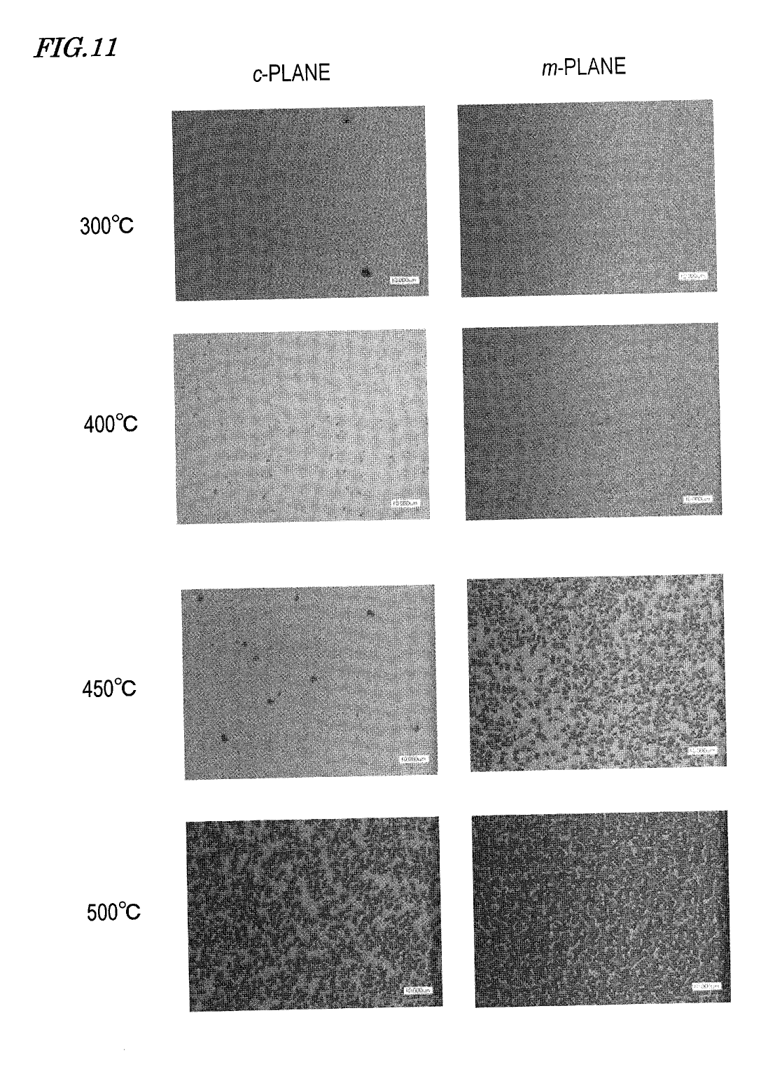

FIG. 11 shows surface pictures of the samples used for the measurements shown in FIGS. 10A and 10B by a laser microscope. FIG. 11 shows the pictures of the growing plane 14 side of the Ag layer corresponding to the p-electrode. A tendency similar to that of the reflectance described above was found in surface (growing plane 14) shapes of the samples. In the case of the samples at the heat-treatment temperature of 450° C. or higher, it is found that the surface morphology suddenly changed on both the m-plane and the c-plane and the surface roughness was increased. It is considered that the reduction in reflectance is due to a change in surface shape and interface shape of the Ag layer due to the heat treatment. However, when the heat treatment was conducted at 450° C. or higher, the surface roughness of the Ag electrode formed on the m-plane was markedly increased as compared with the result obtained for the Ag electrode formed on the c-plane. This tendency is the same as that of the results for the reflectance shown in FIGS. 10A and 10B.

In general, it is known that Ag aggregates by the heat treatment. The aggregation is a phenomenon in which Ag atoms migrate by applied heat to bring about an increase in size of a crystal grain or an increase in surface roughness.

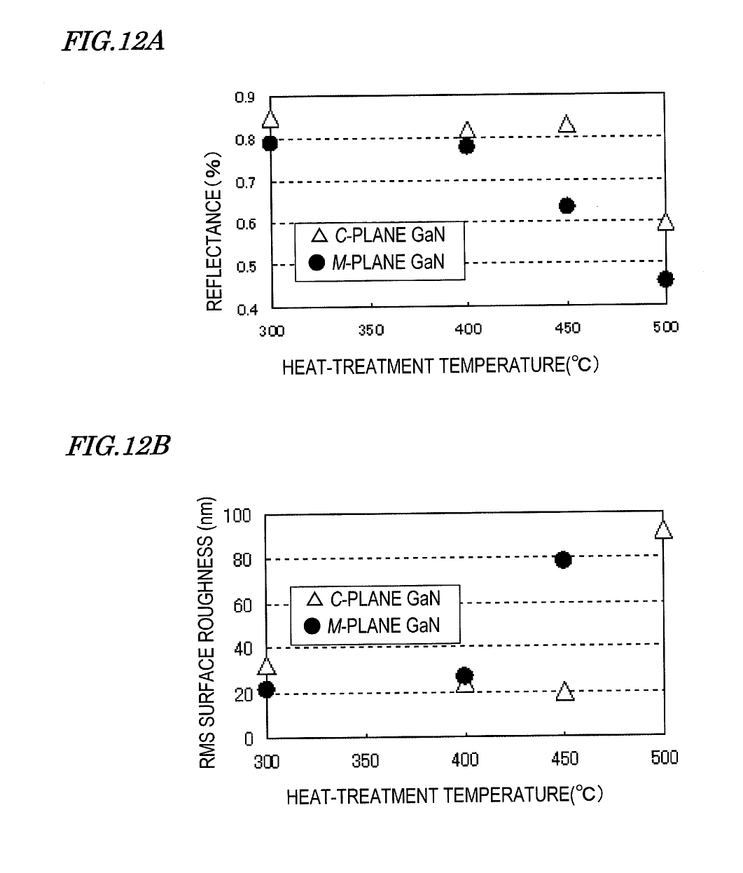

The reduction in reflectance and the change in surface shape by the heat treatment, which are found in the results shown in FIGS. 10A, 10B, and 11, are due to the aggregation of Ag. FIGS. 12A and 12B are graphs showing the summary of the results of the reflectances and the surface roughnesses shown in FIGS. 10A, 10B, and 11. FIG. 12A shows the reflectance of light at the wavelength of 450 nm, and FIG. 12B shows RMS surface roughness measured at a 150-fold magnification by using the laser microscope. The reduction in reflectance and the increase in surface roughness depending on the heat-treatment temperature are more drastic for the Ag electrode formed on the m-plane than for the Ag electrode formed on the c-plane. Specifically, it is found that the effects of aggregation due to the heat treatment differ for the Ag electrode formed on the c-plane differs from those on the Ag electrode formed on the m-plane according to this embodiment.

There exist some reports on the effects of aggregation in the Ag electrode formed on the conventional c-plane nitride-based semiconductor layer and a method for suppressing the reduction in reflectance due to the aggregation (for example, Japanese Patent Application Laid-open No. 2001-308462 and Japanese Patent Application Laid-open No. 2003-332697). The inventor of the present disclosure found that an aggregation suppressing technique unique to the Ag electrode formed on the m-plane was required because the Ag layer formed on the m-plane nitride-based semiconductor layer exhibits an aggregation phenomenon different from that in the case where the Ag layer is formed on the conventional c-plane nitride-based semiconductor layer.

The inventor of the present disclosure conducted a closer examination on the aggregation phenomenon of the Ag electrode formed on the m-plane nitride-based semiconductor layer according to this embodiment. The results are described below.

The Ag crystal is cubical crystal and has a face-centered cubic structure. The Ag aggregation phenomenon described above is strongly correlated with (111)-plane orientation of the Ag crystal. The Ag crystal can be suitably deposited on a semiconductor surface by a technique such as an electron beam evaporation method. A film formed by the technique described above has a polycrystalline structure. The polycrystalline structure of Ag is more likely to have (111)-plane orientation by the application of heat. As compared with a state before the heat treatment, the growth of crystal grains having the (111)-plane orientation and an increase in density thereof occur.

The inventor of the present disclosure focused attention on the strong correlation of the Ag aggregation with the (111)-plane orientation of Ag to quantatively evaluate an aggregation state of Ag. As a result, the inventor of the present disclosure confirmed that the Ag electrode formed on the m-plane nitride-based semiconductor layer according to this embodiment exhibited an aggregation phenomenon different from that exhibited by the Ag electrode formed on the conventional c-plane nitride-based semiconductor layer. The results are now described below.

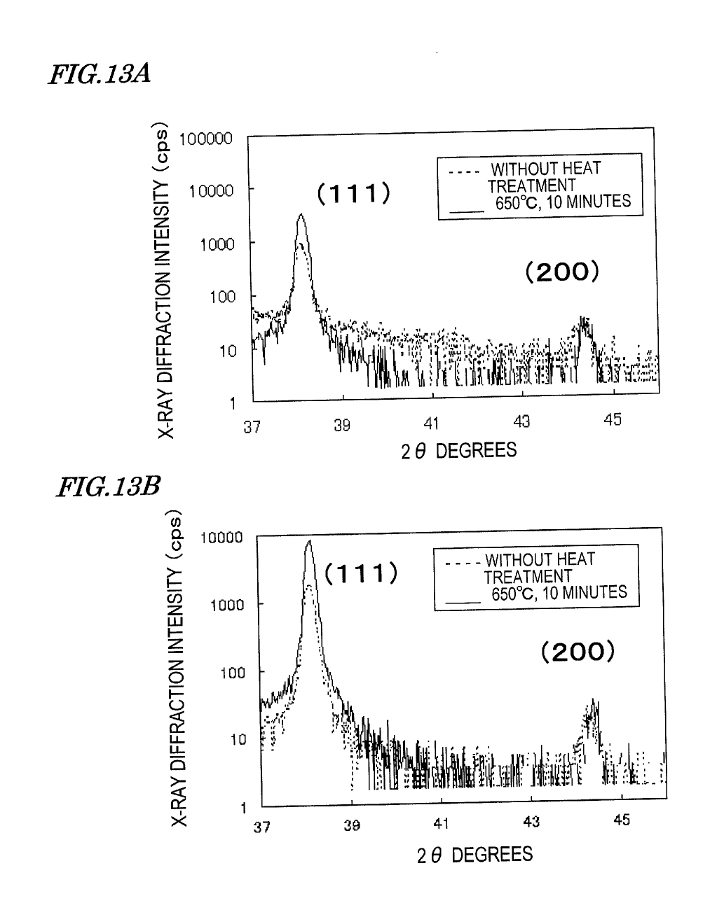

FIGS. 13A and 13B show the results of X-ray diffraction measurements of the Ag electrode 30 formed on the p-type Al_{d}GaₑN layer 25 including the p-type contact layer 26. FIGS. 13A and 13B show the results obtained when an X-ray was radiated from the growing plane 14 side of the Ag electrode 30. FIG. 13A shows the result of measurement of the Ag electrode 30 having a thickness of 400 nm formed on the m-plane, whereas FIG. 13B shows the result of measurement of the Ag electrode 30 having a thickness of 400 nm formed on the c-plane.

FIG. 13B shows, for comparison, the result for the Ag electrode formed under the same conditions as those of the Ag electrode according to this embodiment except that a multilayer structure having the c-plane as the growing plane was used.

A dot line in each of the graphs indicates the result of the X-ray diffraction measurement of a sample without the heat treatment, whereas a solid line in each of the graphs indicates the result of the X-ray diffraction measurement of a sample which was subjected to the heat treatment in the nitrogen atmosphere at 650° C. for 10 minutes.

The X-ray diffraction measurements were conducted using SLX-200 manufactured by RIGAKU Corporation. As an X-ray source, a rotating anticathode X-ray tube using Cu as an anticathode was used. An X-ray focal point was a line focus. The X-ray tube was driven at an X-ray tube voltage of 50 kV and an X-ray tube current of 250 mA. As an optical system, a slit collimation optical system was used. The conditions were as follows. A width of 1 mm and a height of 1 mm were used for an X-ray incident slit, a width of 0.5 mm and a height of 1 mm were used for an S1 slit and an S2 slit, and a width of 1 mm and a height of 2 mm were used for an RS slit corresponding to a light-receiving side slit.

In this measurement, a state of aggregation of Ag was estimated by relatively comparing the X-ray diffraction intensities on the (111)-plane and the (200) plane of Ag. If a width of the slit is too large in this measurement, there is a risk in that a peak which does not satisfy the diffraction conditions is erroneously measured. As a result, there is a possibility that an orientation ratio of orientation of the (111) plane and the (200) plane deviates from an actual value. In addition, if the width of the slit is too large, there is a risk in that a background intensity becomes large to result in a smaller orientation ratio of the (111) plane and the (200) plane than the actual value. Therefore, in the case of this measurement, it is desirable that the measurements be conducted under a small-width slit condition both on the incident side and the light-receiving side. Note that, a background level in this measurement is 2 cps or less on average. If a too small width is used as a slit condition, however, the diffraction on the (200) plane, originally having a relatively small intensity, cannot be measured. In this measurement, the slit conditions described above are used in view of the above-mentioned facts.

For comparison, in FIGS. 13A and 13B, the scales of the vertical axis are set to be the same. A diffraction peak in the vicinity of 2θ=38° corresponds to the diffraction on the (111)-plane of Ag, and a peak in the vicinity of 2θ=44.5° corresponds to the diffraction on the (200)-plane. With the heat treatment, the diffraction intensity on the (111)-plane of Ag suddenly increases. It is considered that the sudden increase is due to the occurrence of aggregation by the application of heat as described above to increase the (111)-plane orientation.

In comparison between the result of the X-ray diffraction measurement on the m-plane and that on the c-plane, the (111)-plane X-ray intensity of the Ag electrode is markedly stronger for the Ag electrode formed on the c-plane than for the Ag electrode formed on the m-plane including the case where the heat treatment is not conducted although the Ag electrodes are vapor-deposited and are subjected to the heat treatment under exactly the same conditions. As described above, the Ag aggregation phenomenon is correlated with the (111)-plane orientation. In view of this fact, it can be said that the aggregation phenomenon differs for the Ag electrode formed on the m-plane nitride-based semiconductor layer according to this embodiment and for the Ag electrode formed on the conventional c-plane nitride-based semiconductor layer. It can be said that this result supports the difference in reflectance described above.

An atomic arrangement on the (111) plane of a cubic system and that on the (0001) plane (c-plane) of a hexagonal wurtzite structure are similar to each other. Therefore, crystal having the (0001) plane (c-plane) of the hexagonal system as a principal plane can be grown on the (111) plane of the cubic system. In view of this fact, it is considered that the Ag crystal having the (111)-plane orientation is likely to be formed on the surface of the above-mentioned c-plane nitride-based semiconductor layer in a stage of vapor deposition of Ag.

For the reasons described above, the (111) plane X-ray diffraction intensity of the Ag electrode formed on the m-plane according to this embodiment has already a smaller value than that of the Ag electrode formed on the c-plane in the stage in which the heat treatment is not conducted. Moreover, the Ag electrode according to this embodiment exhibits the aggregation phenomenon different from that of the Ag electrode formed on the c-plane. Therefore, it is considered that even the result for the dependence of the reflectance on the heat-treatment temperature described above was different from that obtained for the Ag electrode formed on the c-plane.

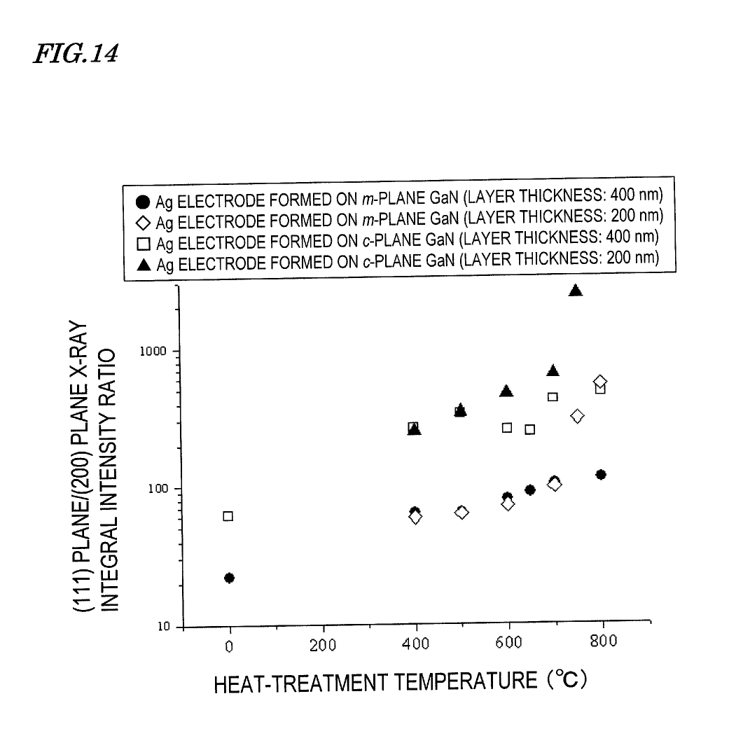

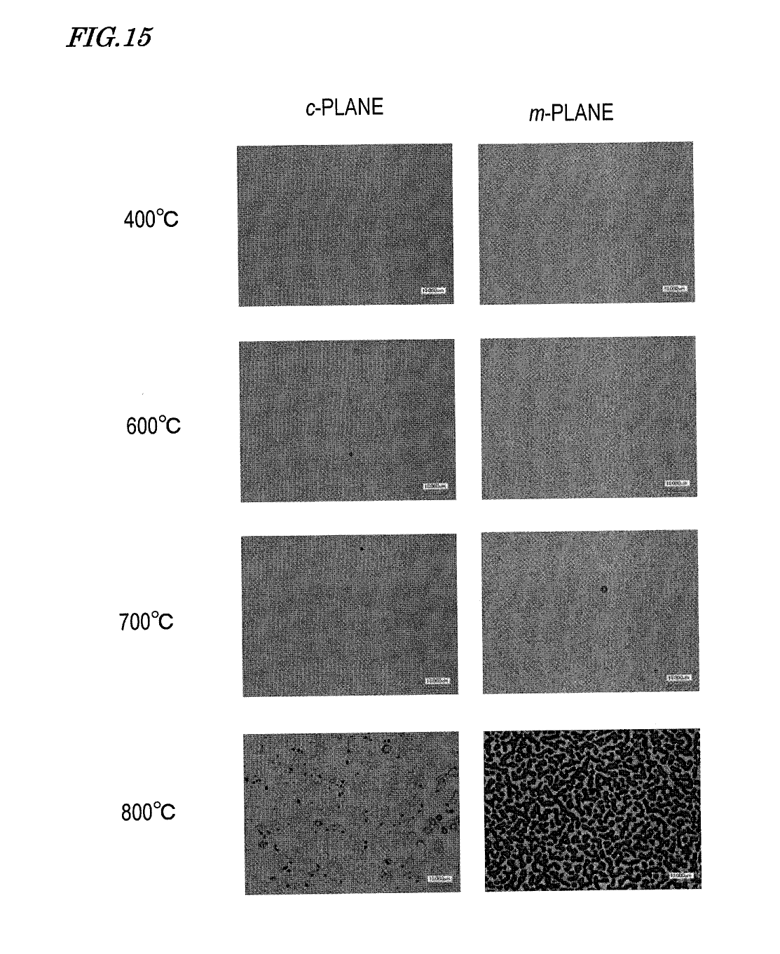

FIG. 14 shows the dependence of the X-ray diffraction peak integral intensity ratio of the (111) plane and the (200) plane of the Ag electrode on the heat-treatment temperature. FIG. 14 shows the X-ray integral intensity ratio obtained when the heat treatment was conducted at a temperature in the range of 400° C. to 800° C. including the case where the heat treatment is not conducted. The heat treatment on the samples used for the results of measurements shown in FIG. 14 was conducted in the nitrogen atmosphere, and the heat-treatment time was uniformly set to about 10 minutes. For comparison, FIG. 14 also shows the results for the Ag electrodes formed under the same conditions as those of this embodiment except that a multilayer structure having the c-plane as the growing plane was used. FIG. 14 shows the results obtained when the X-ray was radiated from the growing plane 14 side of the Ag electrode 30.

When only the diffraction intensity on the (111) plane of Ag is to be compared, there is a possibility that the measurement value changes depending on the intensity of the X-ray, a beam diameter, the thickness of Ag, or the like. In order to avoid the problem described above, the X-ray diffraction intensities on the (111) plane and the (200) plane of Ag were simultaneously measured in this measurement. Then, the ratio of the X-ray diffraction intensities was obtained to evaluate the aggregation state of Ag. Here, the integral intensity ratio is a value obtained by integrating the intensities in the range of ±0.5° from the respective peak positions and obtaining the ratio thereof. The results obtained when the thickness of the Ag layer was set to 200 nm and 400 nm are shown.

As shown in FIG. 14, with an increase in heat-treatment temperature, the integral intensity ratio increased. In comparison between the results obtained when the thickness of the Ag layer was 200 nm and 400 nm, approximately similar tendencies were obtained. From this fact, in the comparison of the intensity ratio of the (111) plane and the (200) plane, it can be said that the thickness dependence is small when the thickness of the Ag layer is 200 nm or more. It is considered that the dependence of the (111) plane/(200) plane integral intensity ratio on the thickness of the Ag electrode 30 is small even if the thickness of the Ag layer becomes larger than 400 nm. It is considered that a variation found in measurement value in a high-temperature range is due to the generation of voids on the surface of Ag by the aggregation.

The results on the Ag electrode formed on the m-plane nitride-based semiconductor layer and on the Ag electrode formed on the c-plane nitride-based semiconductor layer are now compared with each other. In the case of the Ag electrode formed on the c-plane, the integral intensity ratio obtained when the heat treatment was not conducted was about 60, whereas the integral intensity ratio increased to 200 or more when the heat-treatment temperature exceeded 400° C. In this connection, in the case of powdery Ag, it is known that the (111) plane/(200) plane X-ray integral intensity ratio is 100:40 (Jun Ho Son, Yang Hee Song, Hak Ki Yu, and Jong-Lam Lee, Effects of Ni cladding layers on suppression of Ag agglomeration in Ag-based Ohmic contacts on p-GaN. Applied Physics Letters 95, 062108 (2009)). It is understood that the Ag electrode formed on the c-plane has a high integral intensity ratio even in the case where the heat treatment is not conducted and therefore, Ag crystal grains having the (111) plane orientation are present at a high rate. Moreover, it is understood that the rate further increases due to the aggregation occurring at the time of the heat treatment.

On the other hand, in the case of the Ag electrode formed on the m-plane, the (111) plane/(200) plane X-ray integral intensity ratio when the heat treatment is not conducted is about 20, which is smaller than that obtained with the c-plane described above. Even when the heat-treatment temperature is varied from 400° C. to 700° C., the integral intensity ratio has a value of about 100. The difference in integral intensity ratio indicates a difference in aggregation phenomenon of Ag occurring when the heat treatment is conducted, and means that a ratio of the crystal gains having the (111)-plane orientation to the Ag layer is smaller than that of the Ag layer formed on the conventional c-plane due to the aggregation.

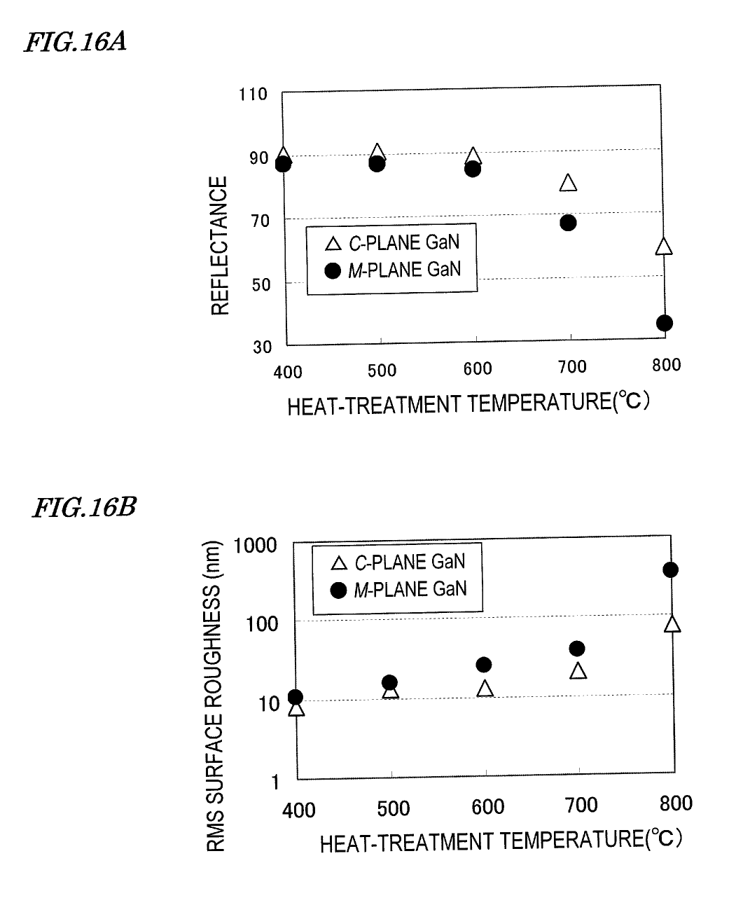

Next, the relation between the X-ray diffraction integral intensity ratio shown in FIG. 14, the reflectance, and a surface morphology is described. FIG. 15 shows pictures of surface morphologies of the Ag electrodes formed on the nitride-based semiconductor layers respectively having the c-plane and the m-plane as the growing plane after the heat treatment. FIG. 16A is a graph showing the relation between the reflectance of each of the Ag electrodes formed at a thickness of 400 nm on the m-plane nitride-based semiconductor layer and the c-plane nitride-based semiconductor layer, and the heat-treatment temperature, and FIG. 16B is a graph showing the relation between the RMS surface roughness of each of the Ag electrodes formed at a thickness of 400 nm on the m-plane nitride-based semiconductor layer and the c-plane nitride-based semiconductor layer, and the heat-treatment temperature. FIG. 16A shows the reflectance with respect to light having a wavelength of 450 nm, and FIG. 16B shows the RMS surface roughness measured at a 150-fold magnification by using a laser microscope.

In comparison with the results for the Ag electrodes having a thickness of 100 nm described above (FIG. 11), the tendencies are similar to each other. When the thickness is increased to 400 nm, a critical heat-treatment temperature, at which the reflectance and the surface roughness degrade, shifted to the high temperature side. In the case of the Ag electrodes having the thickness of 400 nm, when the heat treatment was conducted at a temperature exceeding 600° C., the reduction in reflectance and the degradation of the surface morphology became sharp. This tendency is more remarkable with the Ag electrode formed on the m-plane than with that formed on the c-plane.

From the results shown in FIGS. 11 and 15, it is understood that the degradation of the surface morphology is more suppressed in the case where the thickness of the Ag electrode 30 is 400 nm than in the case where the thickness is 100 nm in comparison between the samples subjected to the heat treatment at the same temperature. It is considered that this tendency is maintained even when the thickness becomes larger than 400 nm.

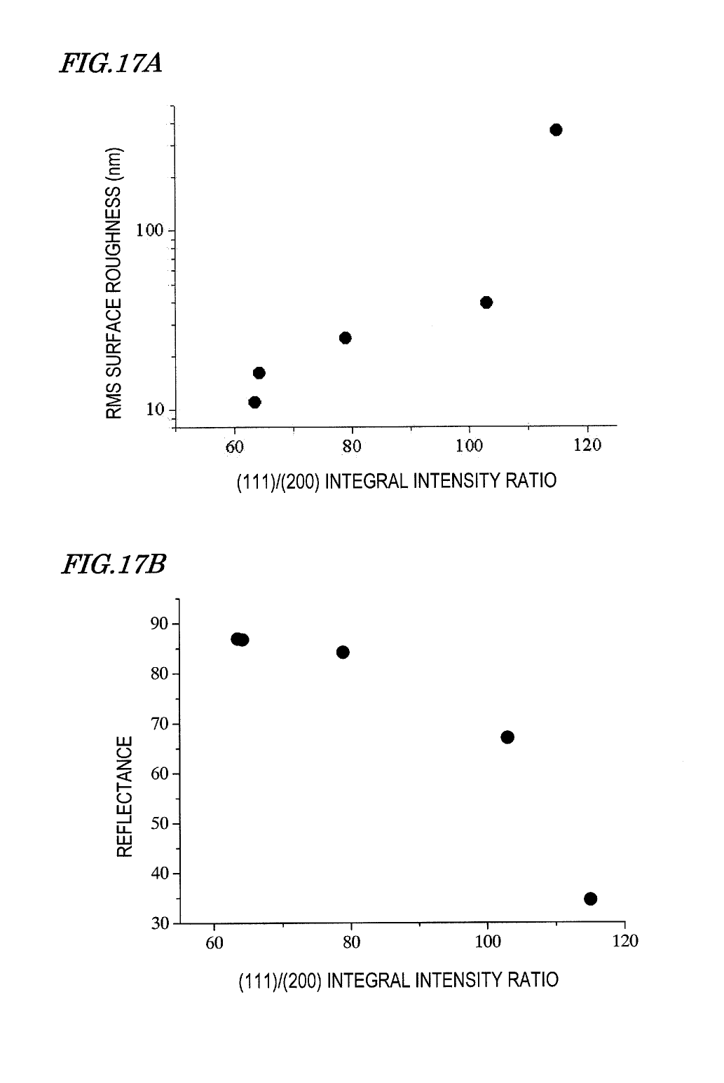

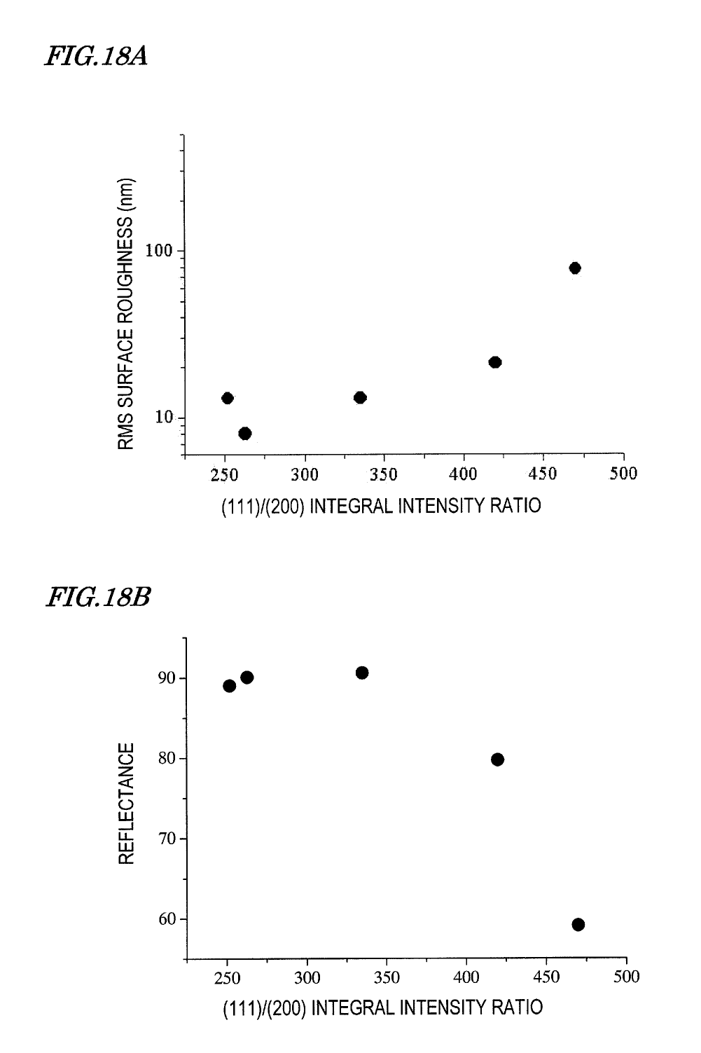

FIGS. 17A and 17B are graphs showing the relation between the (111) plane/(200) plane X-ray integral intensity ratio of the Ag electrode formed on the nitride-based semiconductor layer having the m-plane shown in FIG. 14, and the reflectance and the RMS surface roughness shown in FIGS. 16A and 16B, respectively. For comparison, the results on the Ag electrode obtained when the underlayer is the c-plane nitride-based semiconductor layer are shown in FIGS. 18A and 18B. The scales of the horizontal axis for the integral intensity ratio are different between FIGS. 17A and 17B, and FIGS. 18A and 18B. For both the Ag electrodes formed on the m-plane and the c-plane, the RMS surface roughness increases and the reflectance decreased with an increase in (111) plane/(200) plane X-ray integral intensity ratio. This is due to the aggregation of Ag and is considered to be caused by a change in density of crystal grains having the (111)-plane orientation or the growth of the crystal grains. Further, for the Ag electrode formed on the m-plane nitride-based semiconductor layer according to this embodiment, the reflectance became smaller than 70% and the surface roughness became larger than 30 nm when the integral intensity ratio exceeded 100. On the other hand, for the Ag electrode formed on the nitride-based semiconductor layer having the c-plane, the same changes occurred at a large integral ratio of 350 or more.

It is understood that the reduction in reflectance and the increase in surface roughness due to the heat treatment are strongly correlated with the (111) plane/(200) plane X-ray diffraction intensity ratio of the Ag electrode. The correlation greatly differs between the Ag electrode formed on the conventional c-plane nitride-based semiconductor layer and the Ag electrode formed on the m-plane nitride-based semiconductor layer according to this embodiment. As described above, this difference is due to a difference in aggregation phenomenon between the Ag electrode formed on the c-plane nitride-based semiconductor layer and the Ag electrode formed on the m-plane nitride-based semiconductor layer. Therefore, it is understood that countermeasures different from those for the Ag electrode formed on the conventional c-plane nitride-based semiconductor layer are required to suppress the reduction in reflectance and the increase in surface roughness due to the aggregation for the Ag electrode formed on the m-plane nitride-based semiconductor layer according to this embodiment.

From the above-mentioned results, when the Ag electrode 30 is formed on the p-type Al_{d}GaₑN layer 25 including the p-type contact layer 26 in the nitride-based semiconductor device according to this embodiment, the (111) plane/(200) plane X-ray diffraction integral intensity ratio of the Ag layer after the heat treatment may be designed to 20 or more to 100 or less. When the integral intensity ratio is smaller than 20, the state of the Ag electrode is close to that in the case where the heat treatment is not conducted. Therefore, the degradation of the surface roughness and the reduction in reflectance due to the aggregation are negligibly small. By setting the integral intensity ratio to 100 or less, the generation of holes and voids in the electrode due to the aggregation is small even when the heat treatment is conducted. Therefore, the electrode having high surface flatness and high reflectance can be realized.

In the case of the conventional Ag electrode formed on the c-plane nitride-based semiconductor layer, the (111) plane/(200) plane X-ray diffraction integral intensity ratio is 350 or less so as to realize the Ag electrode having excellent reflectance and surface flatness even after the heat treatment as can be understood from FIGS. 18A and 18B. Therefore, the tendency greatly differs from that of the Ag electrode according to this embodiment.

The above-mentioned (111) plane/(200) plane X-ray diffraction intensity ratio of the Ag electrode 30 according to this embodiment after the heat treatment may be replaced by a peak intensity ratio. In this case, the Ag electrode having high surface flatness (for example, RMS surface roughness of 30 nm or less (measured by a laser microscope under a condition of a magnification of 150 fold)) and high reflectance (for example, 70% or higher) with little generation of holes and voids due to the aggregation at the time of the heat treatment can be realized as long as the range of peak intensity is 30 or more to 150 or less. The result can be obtained from the peak intensities on the (111) plane and the (200) plane of Ag in the results of X-ray diffraction measurements of the Ag electrodes shown in FIGS. 13A and 13B.

It is important to evaluate the state of aggregation in the Ag electrode by the (111) plane/(200) plane X-ray diffraction intensity ratio. There is a possibility that the aggregation of Ag changes due to the effects of moisture or chlorine. For example, even when the heat treatment is conducted under exactly the same conditions, the effects of aggregation on the reflectance and the surface roughness may change by the effects of humidity, sulfuration, and chloridation. Therefore, a technique of controlling fabrication steps and conditions of the Ag electrode so that the X-ray diffraction intensity ratio falls within a desired range is effective in satisfactory suppression of the effects of the aggregation of Ag on the reflectance and the surface roughness.

Next, the relation between the thickness of the Ag electrode 30 according to this embodiment, the heat-treatment conditions, and the reflectance is described.

It is considered that the effects of the aggregation of Ag on the surface roughness and the reflectance become more remarkable as the thickness of the Ag electrode becomes smaller. It is important for the Ag electrode 30 according to this embodiment to have the high reflectance as well as the low contact resistance. As described above, when the heat treatment is conducted at the temperature in the range of 400° C. or more to 600° C. or less, sufficiently low contact resistance is obtained. When the heat treatment is conducted at the temperature in the range of 500° C. or more to 600° C. or less, lower contact resistance can be obtained. Moreover, when the (111) plane/(200) plane X-ray integral intensity ratio is controlled to fall within the range of 20 or more to 100 or less under the heat-treatment condition described above, the reduction in reflectance and shear strength due to the aggregation of Ag can be suppressed.

In the case where the thickness of the Ag electrode 30 is as small as 100 nm, as shown in FIGS. 12A and 12B, the surface roughness increased and the reflectance decreased when the heat-treatment temperature exceeded 400° C. Therefore, in the case where the thickness of the Ag electrode 30 is 100 nm or less, the surface roughness increases and the reflectance decreases if the heat treatment at the temperature in the above-mentioned range of 400° C. to 600° C., which can reduce the contact resistance, is conducted.

On the other hand, as shown in FIG. 16A, when the thickness of the Ag layer is as large as 400 nm, the reflectance is relatively high even when the heat-treatment temperature becomes equal to 600° C. From this result, it is understood that the reflectance depends on the thickness of the Ag electrode.

Therefore, the relation between the thickness of the Ag electrode 30 according to this embodiment and the reflectance was studied. FIG. 19 shows the relation between the thickness of the Ag electrode 30 and the reflectance. As in the case where the measurement method described above is used, the reflectance was measured by radiating light from the semiconductor layer side. The Ag electrodes 30 used in this measurement were all subjected to the heat treatment under the same conditions. The heat treatment was conducted under the nitrogen atmosphere at the temperature of 500° C. for about 10 minutes. The reflectance shown in FIG. 19 is a value obtained when the wavelength of light is 450 nm.

The reflectance of the Ag electrode 30 was saturated when the thickness became 200 nm or more and exhibited a value as high as 80% or higher. Specifically, the reflectance decreased when the thickness was as small as 100 nm. However, when the thickness exceeded 200 nm, the reflectance was substantially constant. Therefore, the dependence of the reflectance on the thickness is small.

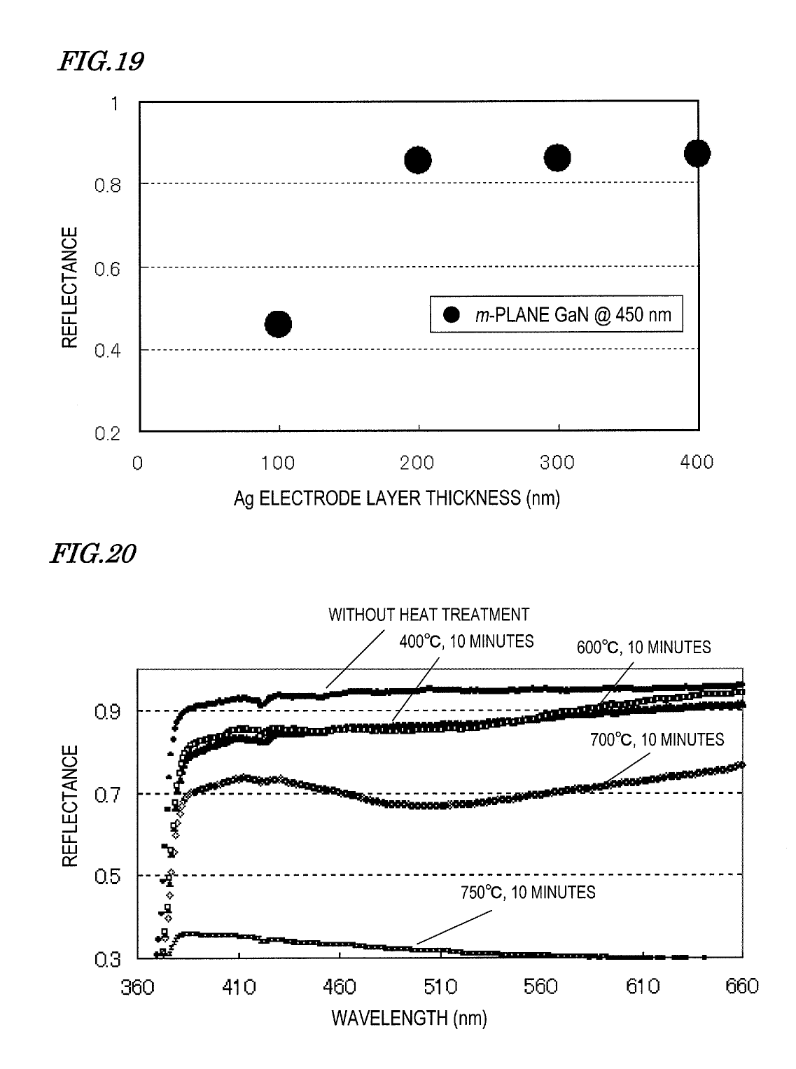

FIG. 20 shows the relation between the reflectance spectrum of the Ag electrode 30 having a thickness of 200 nm and the heat-treatment temperature. In comparison with the case where the thickness is 100 nm, which is shown in FIG. 10A, it is understood that the reduction in reflectance can be suppressed even under the condition of the high heat-treatment temperature when the thickness is increased to 200 nm. As the reflectance obtained when the thickness was 200 nm, a high reflectance of 80% or higher was maintained even when the heat-treatment temperature became equal to 600° C. The reflectance started reducing when the heat-treatment temperature exceeded 700° C.

Specifically, when the Ag electrode 30 is subjected to the heat treatment at a temperature in the above-mentioned range of 400° C. to 600° in which the low contact resistance is obtained, the reduction in reflectance can be suppressed when the thickness of the Ag electrode 30 is 200 nm or more.

In the above-mentioned comparison between the heat-treatment temperature and the (111) plane/(200) plane X-ray integral intensity ratio shown in FIG. 14, there was no great difference between the results at least when the thickness of the Ag electrode 30 was in the range of 200 nm or more to 400 nm or less and therefore, the dependence on the thickness was small. It is considered that the dependence of the (111) plane/(200) plane integral intensity ratio on the thickness of the Ag electrode 30 is similarly small even when the thickness of the Ag electrode 30 is larger than 400 nm.

From the above-mentioned results, it is understood that the contact resistance can be reduced to reduce the surface roughness of the Ag electrode 30 if the heat treatment is conducted at a temperature in the range of 400° C. or more to 600° C. or less on the Ag electrode 30 having a thickness of 200 nm or more.

Next, referring to FIG. 4A again, a specific fabrication method of the nitride-based semiconductor light- emitting device 100 according to this embodiment is described.

First, the substrate 10 is prepared. In this embodiment, an m-plane GaN substrate is prepared as the substrate 10. The GaN substrate of this embodiment is obtained by using a hydride vapor phase epitaxy (HVPE) method.

For example, a thick GaN film is first grown to a thickness of several millimeters on a c-plane sapphire substrate, and then diced perpendicularly to the c-plane, that is, in parallel to the m-plane, thereby obtaining the m-plane GaN substrate. However, the method of fabricating the GaN substrate is not limited to the above-mentioned method. Alternatively, an ingot of bulk GaN may be fabricated by a liquid phase growth process such as a sodium flux process or a melt-growth method such as an ammonothermal process and then diced parallel to the m-plane.

Besides the GaN substrate, for example, a gallium oxide substrate, an SiC substrate, an Si substrate, or a sapphire substrate can be used as the substrate 10. To epitaxially grow an m-plane GaN-based semiconductor on the substrate, the plane orientation of the SiC or sapphire substrate is preferably also an m-plane. However, in some instances, a-plane GaN may grow on an r-plane sapphire substrate. That is why, depending on the growth conditions, the surface on which the crystal growth should take place does not always have to be an m-plane. In any case, at least the surface of the semiconductor multilayer structure 20 should be an m-plane. In this embodiment, crystal layers are formed one after another on the substrate 10 by a metalorganic chemical vapor deposition (MOCVD) process.

Next, the AlᵤGaᵥIn_{w}N layer 22 is formed on the substrate 10. As the AlᵤGaᵥIn_{w}N layer 22, AlGaN is deposited to a thickness of 3 μm, for example. A GaN layer may be deposited by supplying TMG(Ga(CH₃)₃) and NH₃ onto the substrate 10 at 1,100° C., for example.

Subsequently, the active layer 24 is formed on the AlᵤGaᵥIn_{w}N layer 22. In this example, the active layer 24 has a GaInN/GaN multi-quantum well (MQW) structure in which Ga_{0.9}In_{0.1}N well layers and GaN barrier layers each having a thickness of 9 nm, are stacked alternately to have an overall thickness of 81 nm. When the Ga_{0.9}In_{0.1}N well layers are formed, the growth temperature is preferably lowered to 800° C. to introduce In.

Thereafter, an undoped GaN layer is deposited to a thickness of 30 nm, for example, on the active layer 24, and then the p-type Al_{d}GaₑN layer 25 is formed on the undoped GaN layer. As the p-type Al_{d}GaₑN layer 25, p-Al_{0.14}Ga_{0.86}N is deposited to a thickness of 70 nm by supplying TMG, NH₃, TMA(Al(CH₃)₃) gases and Cp₂Mg (cyclopentadienyl magnesium) gas as a p-type dopant, for example.

Next, the p-type contact layer 26 is deposited to a thickness of 0.5 μm, for example, on the p-type Al_{d}GaₑN layer 25. In forming the p-type contact layer 26, Cp₂Mg is supplied as a p-type dopant.

Thereafter, portions of the p-type Al_{d}GaₑN layer 25 including the p-type contact layer 26 and the active layer 24 are removed by performing a chlorine-based dry etching process, thereby forming the recess 42 and exposing a region of the AlₓGa_{y}In_{z}N layer 22 where an n-electrode is to be formed. Then, Ti/Al/Pt layers are deposited as the n-electrode 40 on the region where the n-electrode is to be formed at the bottom of the recess 42.

Further, the Ag electrode 30 is formed at a thickness of 200 nm or more to 1,000 nm or less using a common vapor deposition method (a resistance heating method, an electron beam evaporation process, or the like) on the growing plane 13 of the p-type contact layer 26. The vapor deposition may be conducted at a room temperature or at other temperatures (for example, an arbitrary temperature from 0° C. to 100° C.). The Ag electrode 30 may be formed by sputtering. The Ag electrode 30 is provided for each chip region by a lift-off process.

Next, the heat treatment is conducted on the Ag electrode 30 at a temperature in the range of 400° C. or more to 600° C. or less. The heat treatment is conduced, for example, under the nitrogen atmosphere. Besides the nitrogen atmosphere, the heat treatment can be conducted under air or an atmosphere containing oxygen. Specifically, the heat treatment can be conducted under air, under an atmosphere having a higher oxygen partial pressure than the air, or under an atmosphere having a lower oxygen partial pressure than the air. The heat-treatment temperature is measured by a thermocouple or a radiation thermometer provided in a heat-treatment device.

Thereafter, the substrate 10 and a portion of the AlᵤGaᵥIn_{w}N layer 22 may be removed by a process such as laser lift-off, etching, or polishing. In that case, only the substrate 10 may be removed, or the substrate 10 and a portion of the AlᵤGaᵥIn_{w}N layer 22 may be selectively removed. It is apparent that the substrate 10 and the AlᵤGaᵥIn_{w}N layer 22 may be left without being removed. Through the steps described above, the nitride-based semiconductor light-emitting device 100 of this embodiment is formed.

### Another Embodiment

The light-emitting device according to the embodiment described above may be directly used as a light source. In combination with a resin containing a fluorescent material for wavelength conversion or the like, however, the light-emitting device of this embodiment can be suitably used as a light source with an enlarged wavelength band (for example, a white light source).

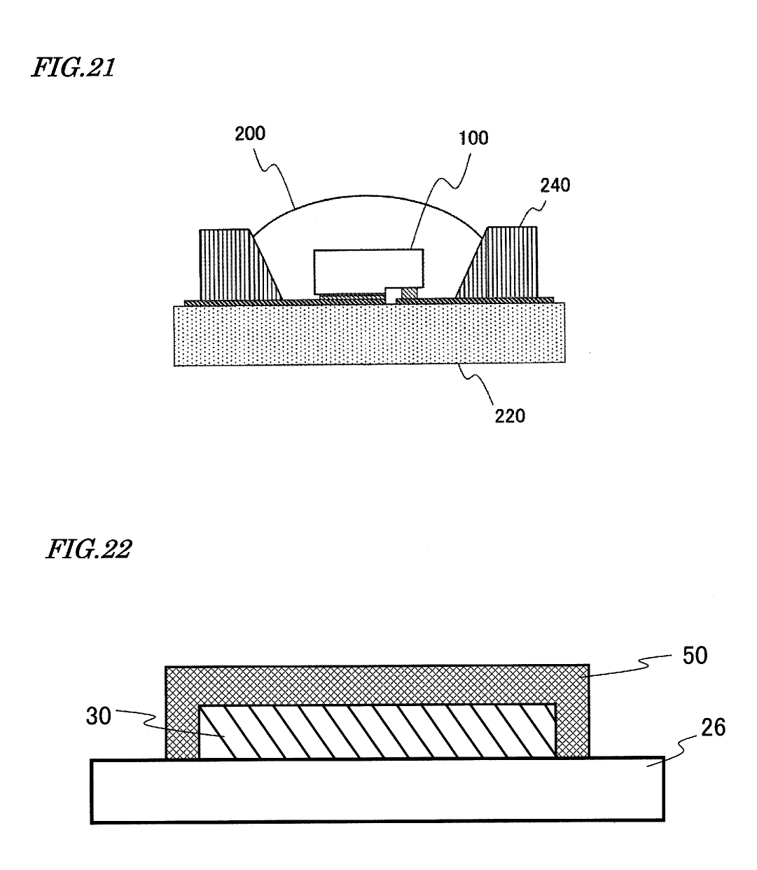

FIG. 21 is a schematic diagram illustrating an example of the white light source described above. The light source illustrated in FIG. 21 includes the light-emitting device 100 having the configuration illustrated in FIG. 4A and a resin layer 200 in which a fluorescence substance (for example, yttrium aluminum garnet (YAG)) for converting a wavelength of light emitted from the light-emitting device 100 into a longer wavelength is dispersed. The light-emitting device 100 is mounted on a support member 220 having a surface on which a wiring pattern is formed. On the support member 220, a reflective member 240 is provided so as to surround the light-emitting device 100. The resin layer 200 is formed so as to cover the light-emitting device 100.

Although the case where the p-type contact layer 26 held in contact with the Ag electrode 30 is made of Ag or AlGaN has been described, the p-type contact layer 26 may be formed from a layer containing In, for example, InGaN. In this case, “In_{0.2}Ga_{0.8}N” with a composition of In set to, for example, 0.2 may be used for a contact layer held in contact with the Ag electrode 30. By adding In to be contained in GaN, a band gap of INₐGa_{b}N (where a+b=1, (a≧0, and b>0) can be made smaller than that of GaN. By the effect of the smaller band gap, activation energy of Mg corresponding to the dopant can be reduced to increase a hole concentration. Therefore, the contact resistance can be reduced. From the above-mentioned fact, the p-type semiconductor region (p-type contact layer 26) held in contact with the Ag electrode 30 only needs to be formed of a gallium nitride (GaN)-based semiconductor or an AlₓGa_{y}In_{z}N (where x+y+z=1, x≧0, y>0, and z≧0) semiconductor.

In this embodiment, each of the AlᵤGaᵥIn_{w}N layer (where u+v+w=1, u≧0, v>0, and w≧0) 22 and the Al_{d}GaₑN layer 25 may be made of a gallium nitride-based compound semiconductor (where v>0 and e>0, respectively).

In this embodiment, as illustrated in FIG. 22, the protective layer 50 may be formed on the Ag electrode 30. By providing the protective layer 50, the effects of moisture on the Ag electrode 30, and the oxidation, sulfuration, and chloridation of the Ag electrode 30 can be prevented to prevent the migration of Ag and the generation of a leak current during energization. The protective layer 50 is formed from a common metal film made of such as, for example, Ti, W, Au, Cu, Ni, Sn, or Pt. A thickness of the protective layer 50 is, for example, 10 nm to 1,000 nm. The protective layer 50 may be an alloy film containing the above-mentioned metals or may have a structure in which layers made of the above-mentioned metals are stacked. The heat treatment on the Ag electrode 30 may be performed after the vapor deposition of the protective layer 50. When the heat treatment is conducted on the Ag electrode 30 before the formation of the protective layer 50, there is an advantage in that alloying between the protective layer and the Ag electrode and the interdiffusion of atoms can be suppressed.

In FIG. 22, the illustration of the components of the nitride-based semiconductor light-emitting device 100 illustrated in FIG. 4A other than the p-type contact layer 26 and the Ag electrode 30 is omitted.

It is apparent that the effects of reduction in contact resistance can be obtained even with a light-emitting device other than the LED (semiconductor laser) and a device other than the light-emitting device (for example, a transistor or a light-receiving device).

The actual growing plane is not necessarily required to be a plane perfectly parallel to the m-plane and may be inclined at a predetermined angle from the m-plane. The angle of inclination is defined by an angle formed by a normal of the actual growing plane of the nitride-based semiconductor layer and a normal of the m-plane (m-plane which is not inclined). The actual growing plane can be inclined from the m-plane (m-plane which is not inclined) toward a direction of a vector represented by a c-axis direction and an a-axis direction. An absolute value of an inclination angle θ is 5° or less, preferably, 1° or less in the c-axis direction. Moreover, the absolute value of an inclination angle θ is 5° or less, preferably, 1° or less in the a-axis direction. Specifically, in the present invention, the “m-plane” includes a plane inclined from the m-plane (m-plane which is not inclined) within the range of ±5° to a predetermined direction. It is considered that a large number of m-plane regions are exposed at the micro level although the growing plane of the nitride-based semiconductor layer is inclined as a whole from the m-plane as long as the inclination angle is within the above-mentioned range. Therefore, it is considered that the plane inclined at the angle of 5° or less in absolute value from the m-plane has the same properties as those of the m-plane. In other words, when the absolute value of the inclination angle θ is equal to or less than 5°, internal quantum efficiency is high avoiding influence of a piezoelectric field. Thus, the absolute value of the inclination angle θ is set to 5° or less.

In the embodiment described above, the p-type Al_{d}GaₑN layer 25 and the p-type contact layer 26 are doped with Mg as the p-type impurities. In exemplary embodiments according to the present disclosure, for example, besides Mg, Zn or Be may be used as the p-type dopant.

The nitride-based semiconductor device 100 of the embodiment described above is, for example, a light-emitting diode or a laser diode in a wavelength band over all the visible range, for example, ultraviolet, blue, green, orange, and white.

This subject matter is suitable for the use for, for example, an electric spectacular or an illumination lamp. Moreover, the application of the subject matter to the fields of display and optical information processing is expected.

While the present invention has been described with respect to exemplary embodiments thereof, it will be apparent to those skilled in the art that the disclosed invention may be modified in numerous ways and may assume many embodiments other than those specifically described above. Accordingly, it is intended by the appended claims to cover all modifications of the invention that fall within the true spirit and scope of the invention.

This application is based on Japanese Patent Application No. 2011-096467 filed on Apr. 22, 2011, the entire contents of which are hereby incorporated by reference.

What is claimed is:

1. A method for fabricating a nitride-based light-emitting device, comprising:
a step (a) of forming a nitride-based semiconductor multilayer structure including a p-type semiconductor region having an m-plane as a growing plane; and
a step (b) of forming an Ag electrode so as to be in contact with the growing plane of the p-type semiconductor region,
wherein the step (b) includes:
a step (b1) of forming the Ag electrode having a thickness in a range of 200 nm or more to 1,000 nm or less; and
a step (b2) of heating the Ag electrode to a temperature in a range of 400° C. or more to 600° C. or less.

2. A method for fabricating a nitride-based semiconductor light-emitting device according to claim 1, wherein the Ag electrode is heated under an atmosphere with an oxygen partial pressure smaller than that of air in the step (b2).

3. A method for fabricating a nitride-based semiconductor light-emitting device according to claim 2, wherein the Ag electrode is heated to the temperature in the range of 500° C. or more to 600° C. or less in the step (b2).

4. A method for fabricating a nitride-based semiconductor light-emitting device according to claim 2, wherein the thickness of the Ag electrode is set in a range of 200 nm or more to 500 nm or less in the step (b1).

5. A method for fabricating a nitride-based semiconductor light-emitting device according to claim 2,
wherein the p-type semiconductor region includes a contact layer containing Mg at a concentration in a range of 4×10¹⁹ cm⁻³ or more to 2×10²⁰ cm⁻³ or less, and
wherein the contact layer is formed of an AlₓGa_{y}In_{z}N semiconductor having a thickness in a range of 26 nm or more to 60 nm or less, where x+y+z=1, x≧0, y>0, and z≧0.

6. A method for fabricating a nitride-based semiconductor light-emitting device according to claim 2, further comprising a step (c) of forming a protective film on the Ag electrode after the step (b).

7. A nitride-based semiconductor light-emitting device fabricated by the method according to claim 2.

8. A nitride-based semiconductor light-emitting device, comprising:
a nitride-based semiconductor multilayer structure including a p-type semiconductor region having an m-plane as a growing plane; and
an Ag electrode provided so as to be in contact with the growing plane of the p-type semiconductor region,
wherein the Ag electrode has a thickness in a range of 200 nm or more to 1,000 nm or less, and
wherein an integral intensity ratio of X-ray intensities on a (111) plane and on a (200) plane on the growing plane of the Ag electrode is in a range of 20 or more to 100 or less.

9. A nitride-based semiconductor light-emitting device, comprising:
a nitride-based semiconductor multilayer structure including a p-type semiconductor region having an m-plane as a growing plane; and
an Ag electrode provided so as to be in contact with the growing plane of the p-type semiconductor region,
wherein the Ag electrode has a thickness in a range of 200 nm or more to 1,000 nm or less, and
wherein a peak intensity ratio of X-ray intensities on a (111) plane and on a (200) plane on the growing plane of the Ag electrode is in a range of 30 or more to 150 or less.

10. A nitride-based semiconductor light-emitting device according to claim 9, wherein the Ag electrode is subjected to heat treatment under an atmosphere with an oxygen partial pressure smaller than that of air.

11. A nitride-based semiconductor light-emitting device according to claim 10, wherein the Ag electrode has a thickness in a range of 200 nm or more to 500 nm or less.

12. A nitride-based semiconductor light-emitting device according to claim 10,
wherein the p-type semiconductor region includes a contact layer containing Mg at a concentration in a range of 4×10¹⁹ cm⁻³ or more to 2×10²⁰ cm⁻³ or less, and
wherein the contact layer is formed of an AlₓGa_{y}In_{z}N semiconductor having a thickness in a range of 26 nm or more to 60 nm or less, where x+y+z=1, x≧0, y>0, and z≧0.

13. A nitride-based semiconductor light-emitting device according to claim 12, wherein the contact layer contains Mg at a concentration in a range of 4×10¹⁹ cm⁻³ or more to 2×10²⁰ cm⁻³ or less and has a thickness in a range of 30 nm or more to 45 nm or less.

14. A nitride-based semiconductor light-emitting device according to claim 10, further comprising a protective film formed on the Ag electrode.

15. A light source, comprising:
a nitride-based semiconductor light-emitting device; and
a wavelength conversion section containing a fluorescent substance for converting a wavelength of light emitted from the nitride-based semiconductor light-emitting device,
wherein the nitride-based semiconductor light-emitting device includes:
a nitride-based semiconductor multilayer structure including a p-type semiconductor region having an m-plane as a growing plane; and
an Ag electrode provided so as to be in contact with the growing plane of the p-type semiconductor region,
wherein the Ag electrode has a thickness in a range of 200 nm or more to 1,000 nm or less, and
wherein an integral intensity ratio of X-ray intensities on a (111) plane and on a (200) plane on the growing plane of the Ag electrode is in a range of 20 or more to 100 or less.

16. A light source according to claim 15, wherein the Ag electrode is subjected to heat treatment under an atmosphere with an oxygen partial pressure smaller than that of air.
